(19) United States
(12) Patent Application Publication
(10) Pub. No.: US 2006/0001097 A1
(43) Pub. Date: Jan. 5, 2006

(54) Semiconductor device and manufacturing method of the same

(76) Inventors: Toshio Nomura, Kawasaki (JP); Kenji Hashimoto, Kawasaki (JP); Teruo Suzuki, Kasugai (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(21) Appl. No.: 10/995,513

(22) Filed: Nov. 24, 2004

(30) Foreign Application Priority Data
Jul. 1, 2004 (JP) 2004-195843

(51) Int. Cl. H01L 21/331; H01L 23/62

(52) U.S. Cl. 257/355; 438/309; 257/356; 257/357

(57) ABSTRACT

A protection transistor which protects an internal transistor in an internal circuit from breakage due to static electricity occurring between power supply pads is provided. A conductivity type of a first p-well constructing a channel of the protection transistor corresponds to a conductivity type of a second p-well constructing a channel of the internal transistor. An impurity concentration of the first p-well is higher than an impurity concentration of the second p-well. Accordingly, drain junction of the protection transistor is sharper than drain junction of the internal transistor, and starting voltage of a parasitic bipolar operation of the protection transistor is lower than that of the internal transistor. Therefore, the internal circuit can be properly protected from an ESD surge.

### CROSS-REFERENCE TO RELATED APPLICATIONS

This application is based upon and claims the benefit of priority from the prior Japanese Patent Application No. 2004-195843, filed on Jul. 1, 2004, the entire contents of which are incorporated herein by reference.

### BACKGROUND OF THE INVENTION

1. Field of the Invention

The present invention relates to a semiconductor device enhanced in electrostatic resistance and a manufacturing method of the same.

2. Description of the Related Art

A semiconductor device is provided with a protection circuit for protecting an internal circuit of the semiconductor device from electrostatic surge which occurs to power supply pads (Vdd, Vss) and an input and output signal (I/O) pad. FIG. 1 is a circuit diagram showing an outline of the protection circuit.

When electrostatic surge occurs to an I/O pad 102, the electrostatic surge is discharged to a Vdd pad 103 or a Vss pad 104 via a pMOS transistor 105 or an nMOS transistor 106, which are ESD (electrostatic discharge) protection elements connected to the I/O pad 102 and constitute an ESD protection circuit 108. Therefore, an electric current does not flow into the internal circuit 101 connected to the I/O pad 102, and the internal circuit 101 is protected.

Meanwhile, when electrostatic surge occurs between the Vdd pad 103 and the Vss pad 104, the electrostatic surge is discharged via an nMOS transistor 107 connected between them. Therefore, in this case, the electric current does not flow into the internal circuit 101, either.

The important matter concerning the ESD protection circuit is to flow ESD surge to the ESD protection element instead of flowing the ESD surge into the internal circuit 101. When the ESD surge occurs to the I/O pad 102, the ESD surge flows into the ESD protection element and is discharged instead of flowing into the internal circuit 101, since there is a resistance element for separation between the I/O pad 102. and the internal circuit 101. Meanwhile, a resistance element for separation is not connected between the Vdd pad 103 and the internal circuit 101. This is because the power supply potential in the normal operation is reduced and the performance of the internal circuit 101 is reduced if a resistance element is interposed between the internal circuit 101 and the Vdd pad 103. Accordingly, when the ESD surge occurs to the Vdd pad 103, electric current may flow into the internal circuit 101 instead of the power supply clamping circuit 109 depending on the constitution of the internal circuit 101, and the internal circuit 101 is sometimes broken.

Related arts are disclosed in Japanese Patent Application Laid-open No. Hei 10-290004, Japanese Patent Application Laid-open No. 2001-308282, and Japanese Patent Application Laid-open No. 2002-313949.

### SUMMARY OF THE INVENTION

The present invention has its object to provide a semiconductor device capable of reliably protecting an internal circuit and a manufacturing method of the same.

As a result of repeatedly making an earnest study to solve the aforementioned problem, the inventor has conceived the modes of the invention which will be shown hereinafter.

A semiconductor device according to the present invention has an internal transistor constructing an internal circuit, and a protection transistor which protects the internal transistor from breakage due to static electricity occurring between power supply pads. A conductivity type of a channel of the protection transistor corresponds to a conductivity type of the internal transistor, and drain junction of the protection transistor is sharper than drain junction of the internal transistor.

In a manufacturing method of a semiconductor device according to the present invention, an internal transistor constructing an internal circuit, and a protection transistor which protects the internal transistor from breakage due to static electricity occurring between power supply pads are formed. A conductivity type of a channel of the protection transistor is made to correspond to a conductivity type of the internal transistor, and drain junction of the protection transistor is made sharper than drain junction of the internal transistor.

### BRIEF DESCRIPTION OF THE DRAWINGS

FIG. 1 is a circuit diagram showing an outline of a protection circuit;

FIG. 2 is a schematic plane view showing a chip layout according to a first embodiment of the present invention;

FIG. 3 is a schematic plan view showing a layout of a semiconductor device according to the first embodiment of the present invention;

FIG. 4 to FIG. 13 are sectional views showing a manufacturing method of a semiconductor device according to a first embodiment of the present invention in the order of process steps;

FIG. 14 to FIG. 22 are sectional views showing a manufacturing method of a semiconductor device according to a second embodiment of the present invention in the order of process steps;

FIG. 23 to FIG. 31 are sectional views showing a manufacturing method of a semiconductor device according to a third embodiment of the present invention in the order of process steps;

FIG. 32 to FIG. 45 are sectional views showing a manufacturing method of a semiconductor device according to a fourth embodiment of the present invention in the order of process steps;

FIG. 46 to FIG. 53 are sectional views showing a manufacturing method of a semiconductor device according to a fifth embodiment of the present invention in the order of process steps; and

FIGS. 54A and 54B are characteristic charts showing a process condition dependence obtained in a device simulation and an actual measured characteristics obtained from a TLP measurement of an actual wafer.

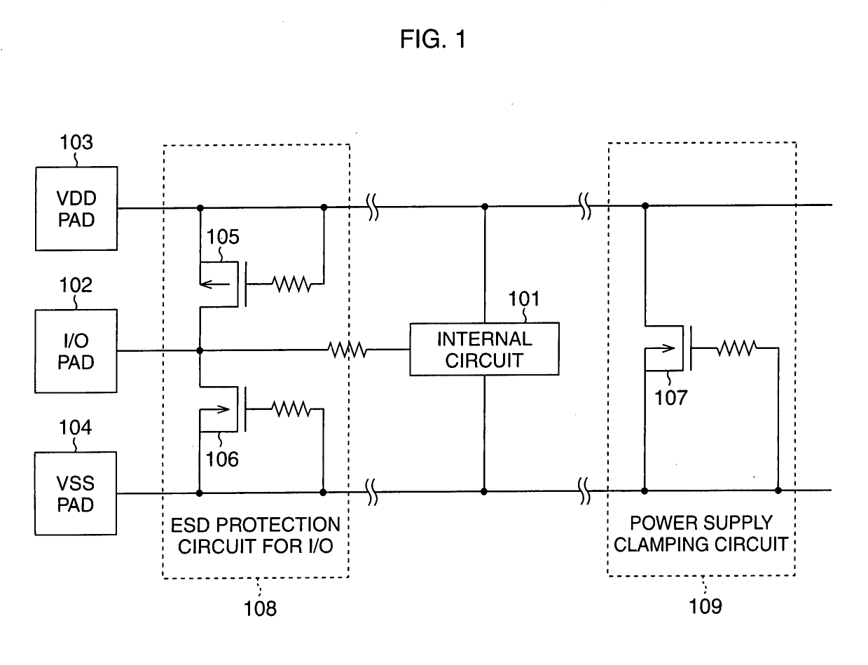

### DETAILED DESCRIPTION OF THE PREFERRED EMBODIMENTS

Hereinafter, embodiments of the present invention will be explained concretely with reference to the attached drawings. It should be noted that the structure of a semiconductor device will be explained. with a manufacturing method of the same for convenience.

-First Embodiment-

A first embodiment of the present invention will be explained in the first place.

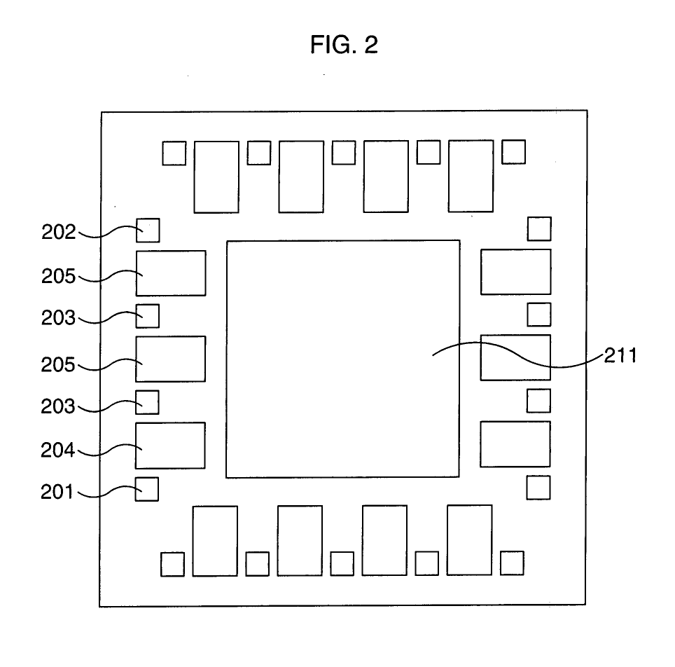

FIG. 2 is a schematic plane view showing a chip layout in the present embodiment.

This semiconductor chip is constructed, for example, by forming a Vdd pad 201, a Vss pad 202, an input and output (I/O) pad 203, a power supply clamping circuit 204, an I/O circuit 205 and the like around an internal circuit 211. This constitution is substantially the same in the basic structure as in a second to fifth embodiments which will be described later.

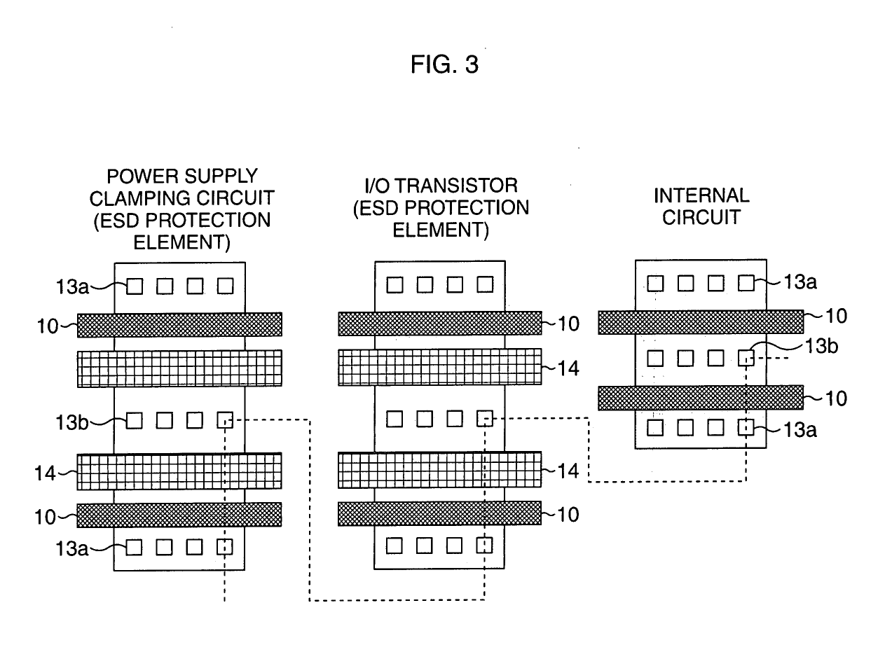

FIG. 3 is a schematic plane view showing a layout of a semiconductor device in this embodiment.

A power supply clamping circuit, an I/O circuit and an internal circuit are respectively constructed with MOS transistors, and in each of these MOS transistors, a source 13a and a drain 13b are formed on both sides of a gate electrode 10 and a silicide block 14 adjacent thereto.

When a high-speed logic product is manufactured, a silicide technique is sometimes used for the pursuit of high-speed performance, and the silicide technique is used for the transistor constructing an internal circuit. It is known that when the silicide technique is applied to the nMOS transistor and the pMOS transistor which are used for an I/O circuit, ESD resistance is extremely reduced, and a so-called silicide block technique which does not silicide a part of the drain of a protection transistor is sometimes used. The same thing applies to the transistors in the power supply clamping circuit. The basic structure of this constitution is substantially the same in the second to fifth embodiments which will be described later.

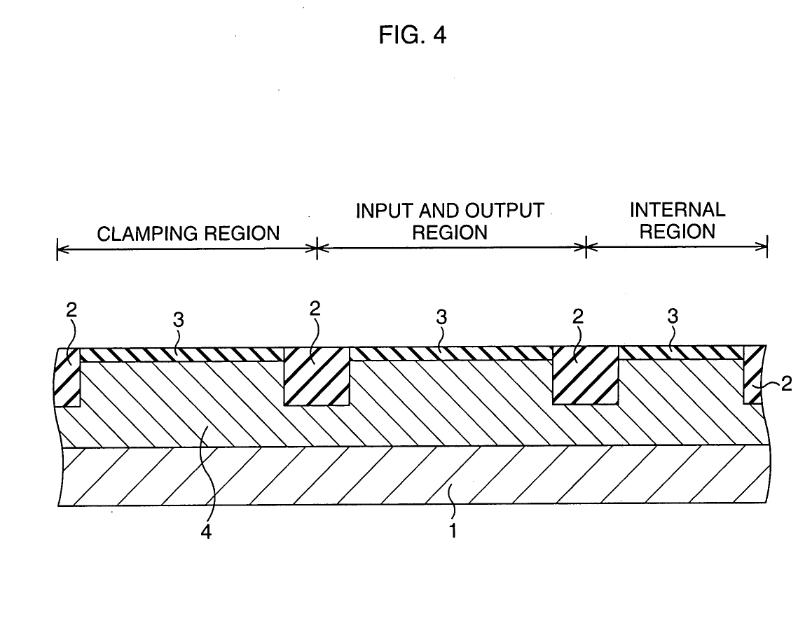

FIG. 4 to FIG. 13 are sectional views showing the manufacturing method of the semiconductor device according to the first embodiment in the order of the process steps. Each of the drawings shows a region in which the nMOS transistor in the power supply clamping circuit is formed, a region in which the nMOS transistor as the I/O ESD protection element is formed, and a region in which the nMOS transistor in the internal circuit is formed. The regions will be called a clamping region, an input and output region and an internal region in the order of the above description for convenience, hereinafter. In the present embodiment, nMOS transistors of the gate length of 0.34 μm, the thickness of the gate insulation film of 8 nm and the operating voltage of 3.3 V are formed in each of the clamping region, the input and output region and the internal region.

In the present embodiment, an element isolation insulating film 2 is formed on a surface of an Si substrate 1 by STI (Shallow Trench Isolation) first as shown in FIG. 4. Next, an Si oxide film 3 of the thickness of about 10 nm, for example, is formed by thermally oxidizing the surface of the Si substrate 1. Next, a resist mask (not shown) which exposes regions in which the nMOS transistors are formed is formed by a photolithography technique. Thereafter, p-wells 4 are formed by performing ion implantation of boron ion by using this resist mask. In formation of the p-wells 4, for example, boron ion is ion-implanted with the energy of 300 keV and the dose amount of 3.0×1013, and thereafter boron ion is ion-implanted with the energy of 100 keV and the dose amount of 2.0×10¹². The resist mask is removed after the latest ion implantation.

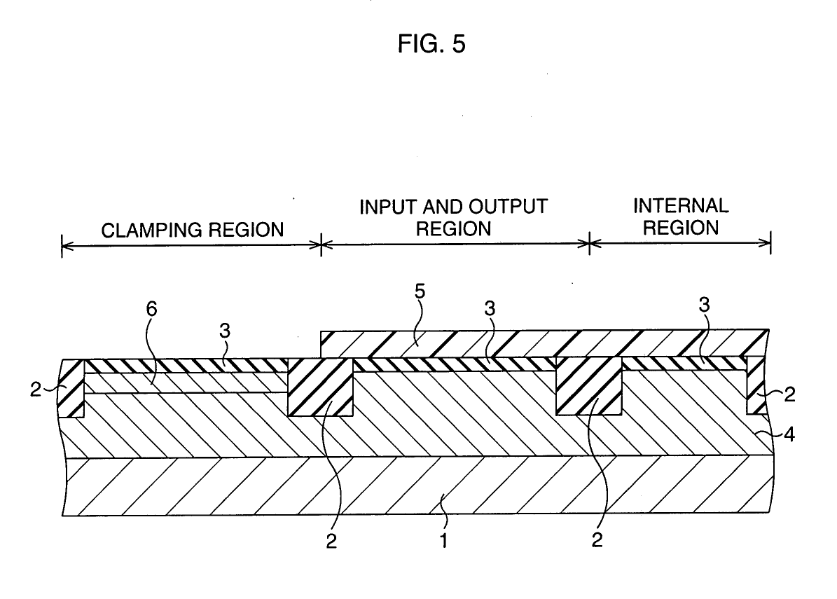

Subsequently, as shown in FIG. 5, a resist mask 5 which exposes the clamping region is formed by a photolithography technique. Next, a p-well 6 is formed in the clamping region by ion-implanting boron ion with the energy of 30 keV and the dose amount of 8×10¹³ by using the resist mask 5.

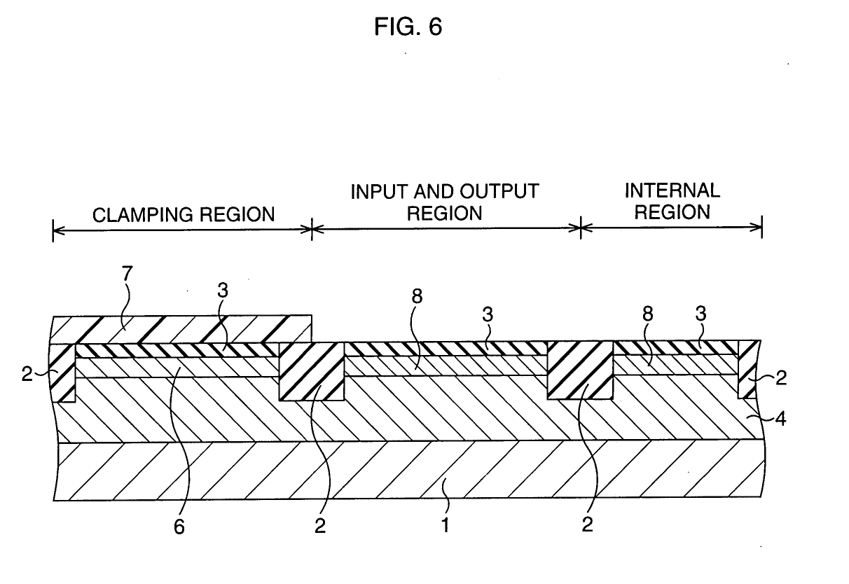

Next, as shown in FIG. 6, after the resist mask 5 is removed, a resist mask 7 which exposes the input and output region and the internal region is formed by a photolithography technique. Subsequently, by using this resist mask 7, boron ion is ion-implanted with the energy of 30 keV and the dose amount of 5×10¹², and thereby p-wells 8 are formed in the input and output region and the internal region. As a result, the impurity concentration of the p-well 6 in the clamping region becomes higher than the impurity concentration of the p-well 8 in the internal region. Without the resist mask 7, ion implantation may be simultaneously performed in the clamping region.

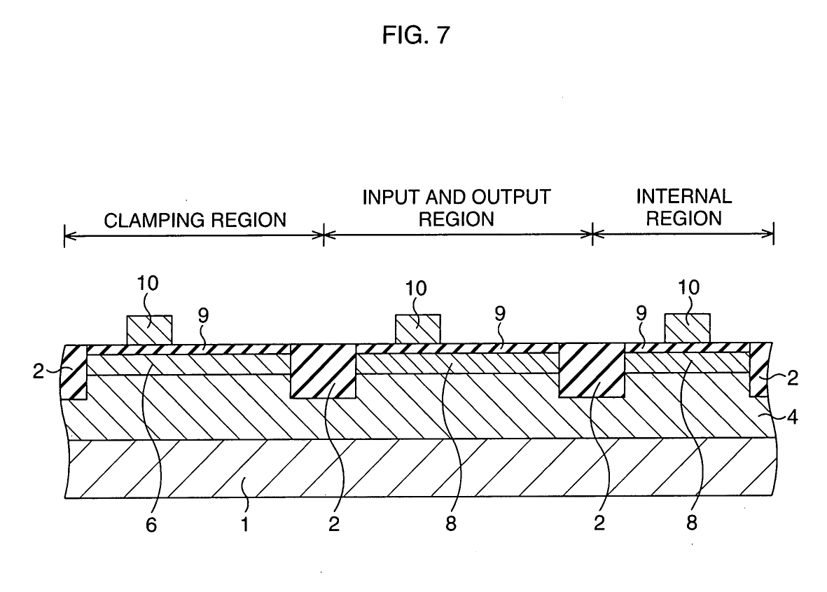

Next, as shown in FIG. 7, after the Si oxide film 3 is removed, by performing thermal oxidation again, a gate oxide film 9 of the thickness of 8 nm is formed. Next, after a polycrystalline Si film is formed on the entire surface by a CVD (Chemical Vapor Deposition) method, the polycrystalline Si film is patterned by a photolithography technique and an etching technique, and thereby gate electrodes 10 are formed.

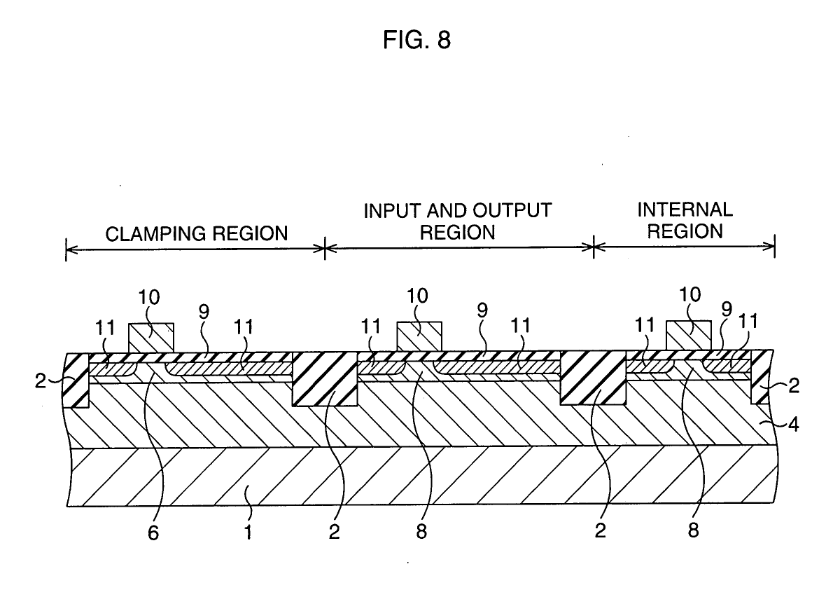

Thereafter, as shown in FIG. 8, a resist mask (not shown) which exposes the regions in which the nMOS transistor are formed is formed by a photolithography technique, and by performing ion implantation of phosphorus ion by using this resist mask, n⁻ diffusion layers 11 are formed. In forming the n⁻ diffusion layer 11, for example, phosphorus ion is ion-implanted with the energy of 35 keV and the dose amount of 4×10¹³. After the ion implantation, the resist mask is removed.

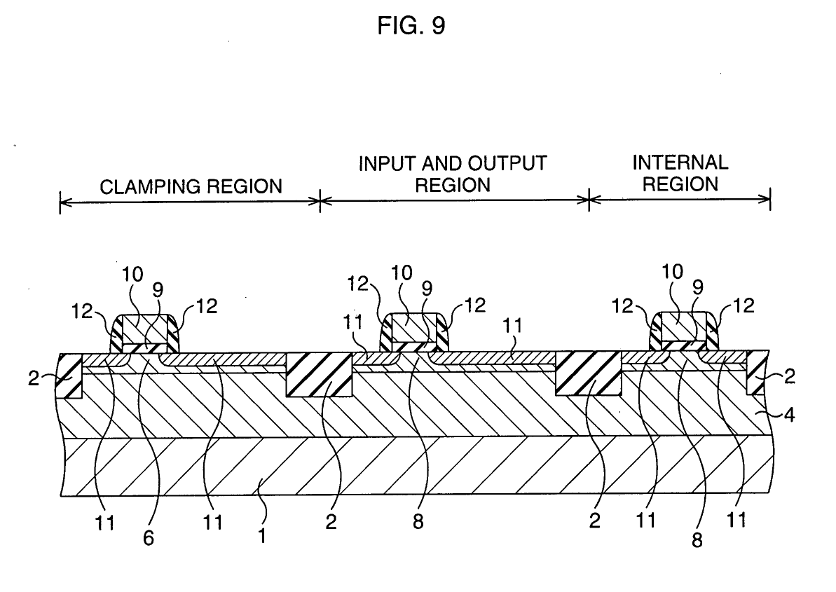

Subsequently, as shown in FIG. 9, an Si oxide film of the thickness of about 130 nm is formed on the entire surface by, for example, a CVD method, and by applying anisotropic etching to the film, side wall spacers 12 are formed at the sides of each of the gate electrodes 10.

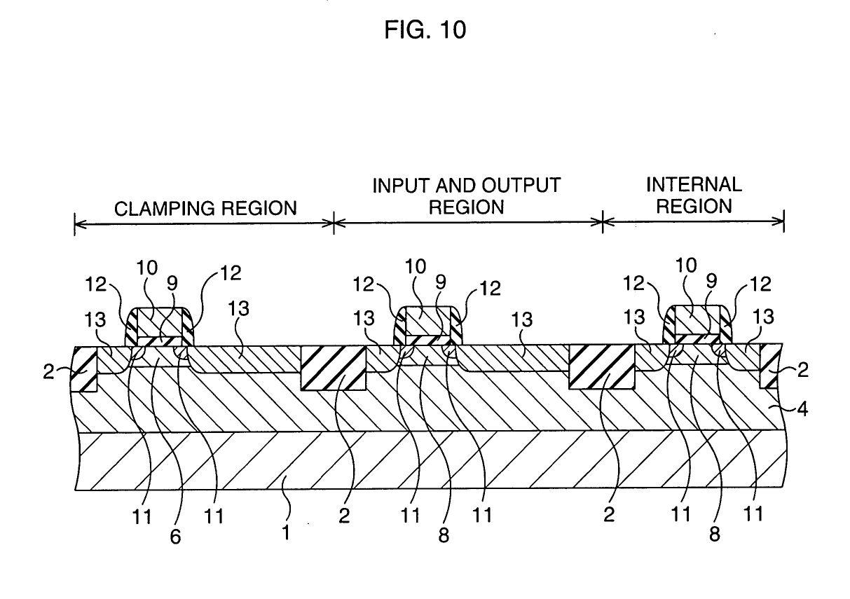

Next, as shown in FIG. 10, a resist mask (not shown) which exposes the regions in which the nMOS transistors are formed is formed by a photolithography technique, and by performing ion implantation of phosphorus ion by using the resist mask, n⁺ diffusion layers 13 are formed. In formation of the n⁺ diffusion layer 13, for example, phosphorus ion is ion-implanted with the energy of 15 keV and the dose amount of 7'10¹⁵. The resist mask is removed after the ion implantation, and, for example, rapid thermal annealing (RTA) at 1000° C. is performed for about ten seconds under nitrogen atmosphere, whereby the impurities in the n⁻ diffusion layers 11 and the n⁺ diffusion layers 13 are activated. As a result of this, source diffusion layers and drain diffusion layers are formed.

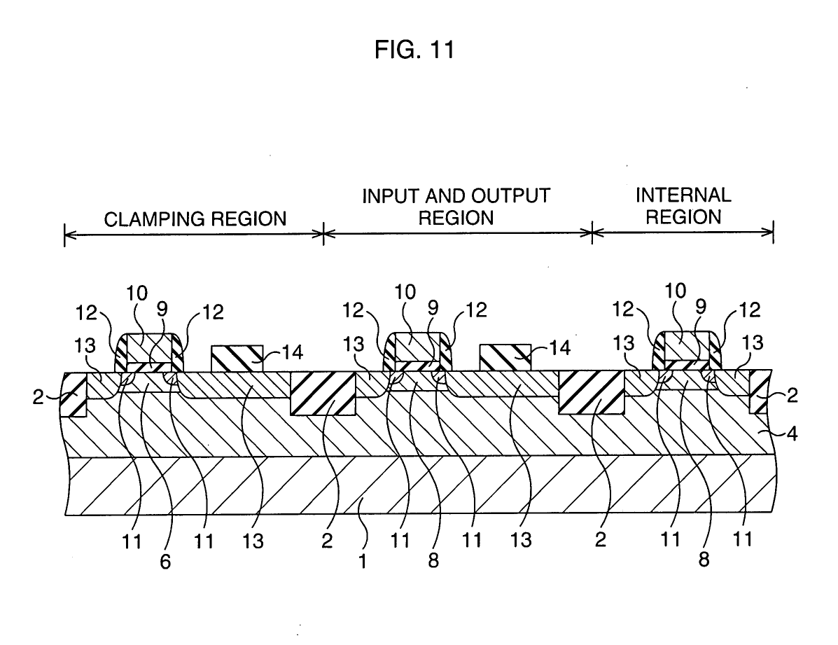

Next, as shown in FIG. 11, after an Si oxide film is formed on the entire surface by a CVD method, the Si oxide film is patterned by a photolithography technique and an etching technique, and thereby silicide blocks 14 are formed on the drain diffusion layers in the clamping region and the input and output region.

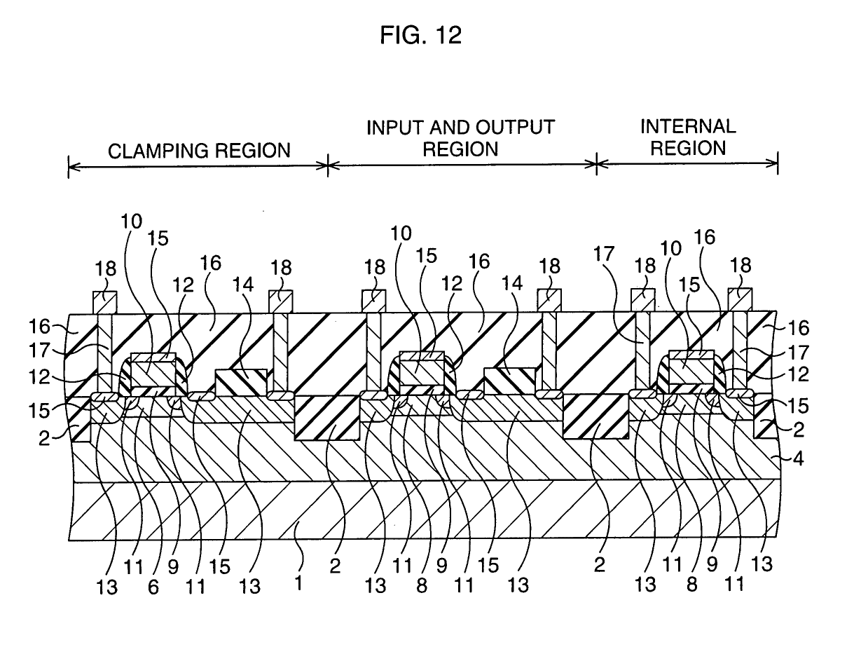

Next, as shown in FIG. 12, silicide layers 15 are formed on the surfaces of the gate electrodes 10 and the n⁺ diffusion layers 13. In this case, the silicide layer 15 is not formed in the region of the surface of the n⁺ diffusion layer 13 where the silicide blocks 14 are formed. Subsequently, an interlayer insulation film 16 is formed on the entire surface, and contact holes are formed in the interlayer insulation film 16. Next, contact plugs 17 are formed in the contact holes, and wirings 18 are formed on the interlayer insulation film 16.

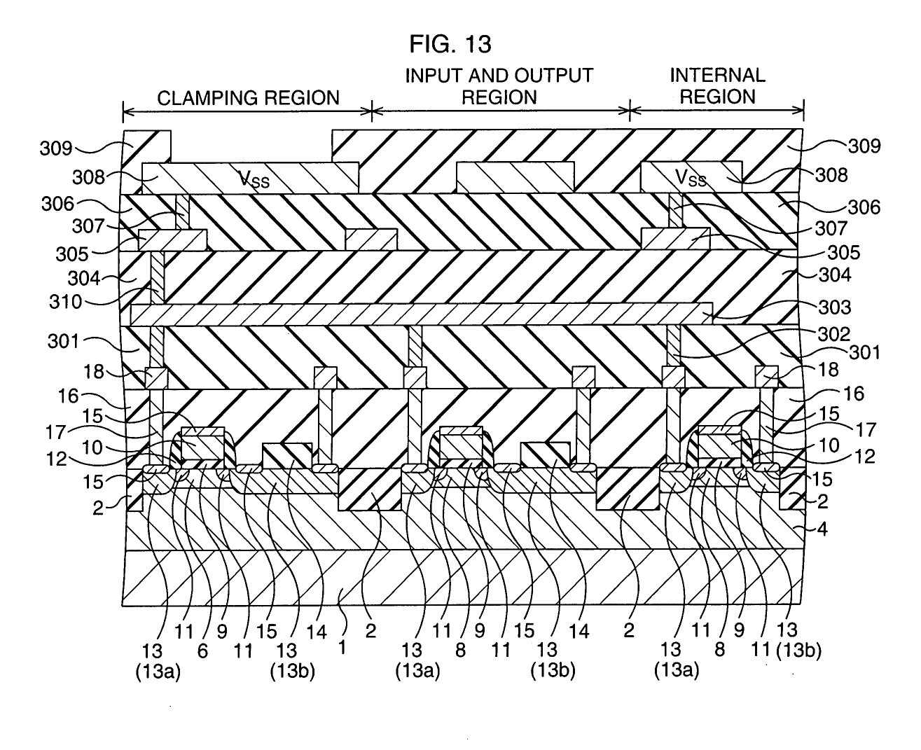

Thereafter, as shown in FIG. 13, an insulation film 301 which covers the wirings 18, contact plugs 302 in the insulation film 301 and connected to the wirings 18, wirings 303 which are connected to the contact plugs 302, an insulation film 304 which covers the wirings 303, contact plugs 310 in the insulation film 304 and connected to the wirings 303, wirings 305 which are connected to the contact plugs 310, an insulation film 306 which covers the wirings 305, contact plugs 307 in the insulation film 306 and connected to the wirings 305, Vss pads 308 which are connected to the contact plugs 307, and an insulation film 309 which covers various kinds of pads including the Vss pads 308 are sequentially formed, and thereby the semiconductor device is completed. In this case, the insulation film 309 is processed so that a part of the surface of the Vss pad 308 is exposed. The source (13a) of each transistor is electrically connected to the pad 308, the drain of the I/O transistor is electrically connected to the I/O pad, and the drain of the power supply clamping transistor is electrically connected to the Vdd pad.

In the semiconductor device according to the first embodiment thus manufactured, the impurity concentration of the p-well 6 in the clamping region is higher than the impurity concentration of the p-well 8 in the internal region. Namely, the impurity concentration of a channel in the clamping region is higher than the impurity concentration of the channel in the internal region. Therefore, junction of drain ends in the clamping region is sharper than that in the internal region, and the frequency of occurrence of the avalanche multiplication phenomenon becomes higher in the clamping region. As a result, the substrate potential easily rises in the clamping region, the voltage which starts the parasitic bipolar operation of the nMOS transistor in the clamping region, namely, the voltage which causes snap-back becomes lower than that of the nMOS transistor in the internal region. Accordingly, even if the ESD surge occurs to the power supply pad, the nMOS transistor in the clamping region is brought into the ON state prior to the nMOS transistor in the internal region, and therefore over current does not flow into the internal circuit, thus protecting the internal circuit. Since no measure is taken to enhance ESD performance for the internal circuit, reduction in the performance of the internal circuit accompanying such a measure does not occur.

The silicide block 14 may not formed.

-Second Embodiment-

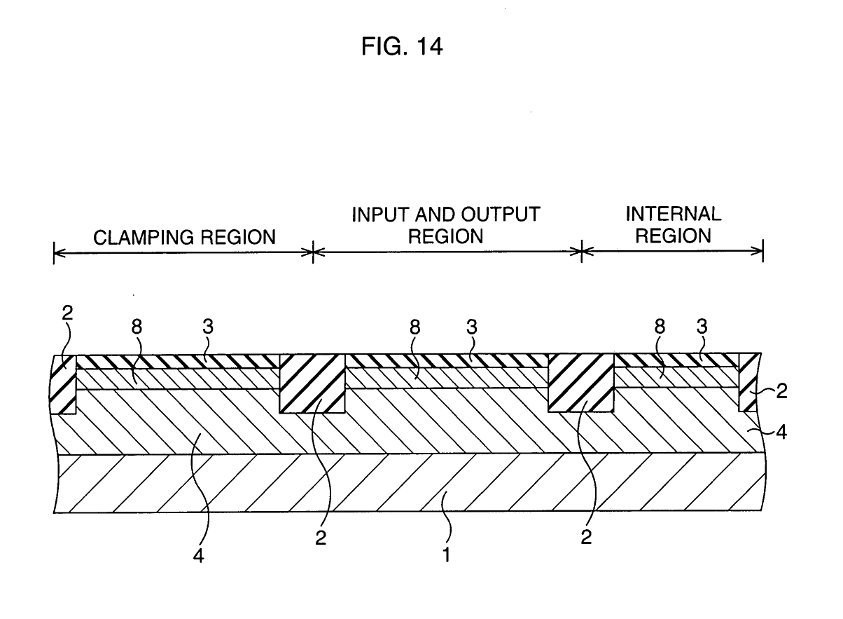

Next, a second embodiment of the present invention will be explained. FIG. 14 to FIG. 22 are sectional views showing a manufacturing method of a semiconductor device according to the second embodiment of the present invention in the order of the process steps. In the present embodiment, nMOS transistors of the gate length of 0.34 μm, the thickness of the gate insulation film of 8 nm and the operating voltage of 3.3 V are also formed in each of the clamping region, the input and output region and the internal region.

In the present embodiment, as shown in FIG. 14, an element isolation insulating film 2 is formed on the surface of an Si substrate 1 by STI first. Next, an Si oxide film 3 of the thickness of about 10 nm, for example, is formed by thermally oxidizing the surface of the Si substrate 1. Next, p-wells 4 are formed as in the first embodiment. In formation of the p-well 4, for example, boron ion is ion-implanted with the energy of 300 keV and the dose amount of 3.0×10¹³, and thereafter boron ion is ion-implanted with the energy of 100 keV and the dose amount of 2.0×10¹². Further, boron ion is ion-implanted with the energy of 30 keV and the dose amount of 5×10¹², and thereby p-wells 8 are formed in the clamping region, the input and output region and the internal region.

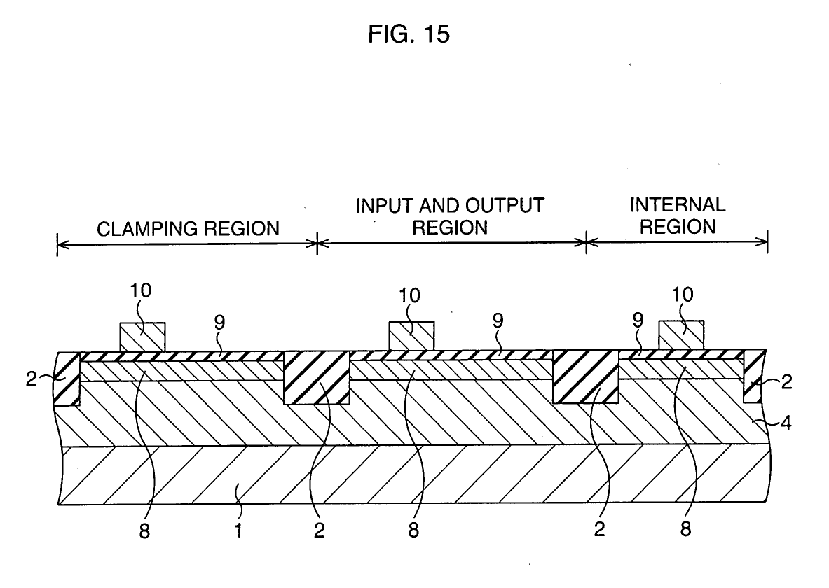

Subsequently, as shown in FIG. 15, after the Si oxide film 3 is removed, by performing thermal oxidation again, a gate oxide film 9 of the thickness of 8 nm is formed. Next, the gate electrodes 10 are formed as in the first embodiment.

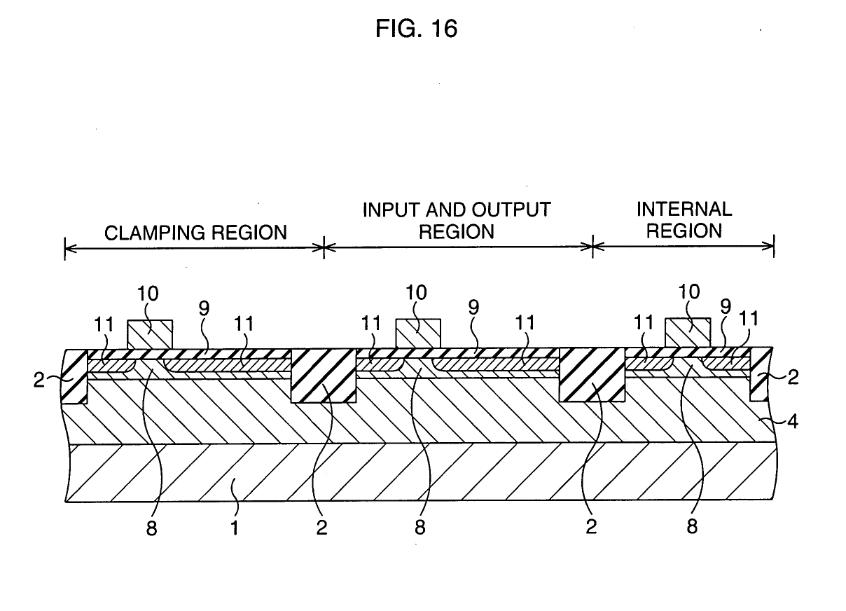

Next, as shown in FIG. 16, n⁻ diffusion layers 11 are formed as in the first embodiment. In formation of the n⁻ diffusion layer 11, for example, phosphorus ion is ion-implanted with the energy of 35 keV and the dose amount of 4×10¹³.

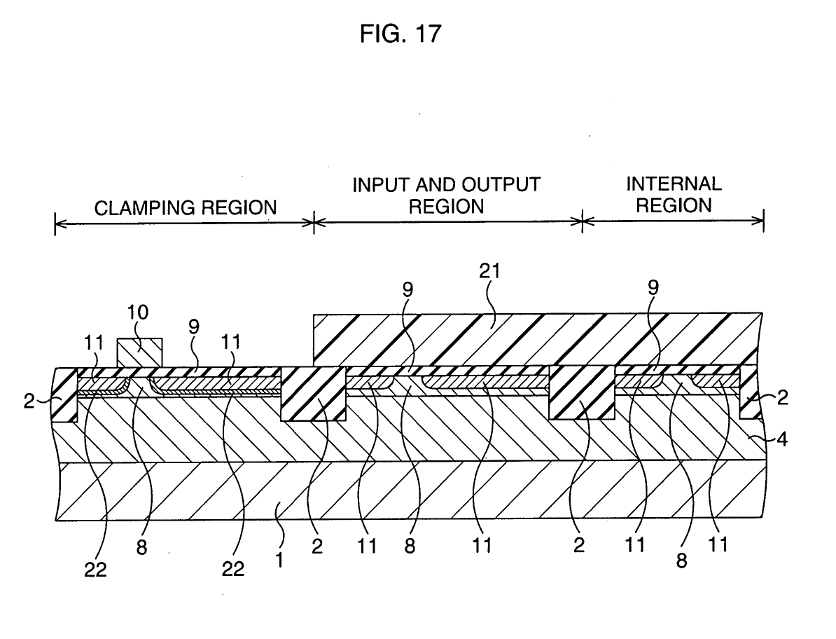

Thereafter, as shown in FIG. 17, a resist mask 21 which exposes the clamping region is formed by a photolithography technique. Next, pocket layers 22 are formed in the vicinity of an interface of the p-well 8 and the n⁻ diffusion layers 11 in the clamping region by ion-implanting BF₂ ion by using the resist mask 21. In formation of the pocket layer 22, BF₂ ion is implanted with the energy of 35 keV and the dose amount of 1×10¹³ from the direction inclined 10° to 45° from the perpendicular direction to the surface of the Si substrate 1, for example.

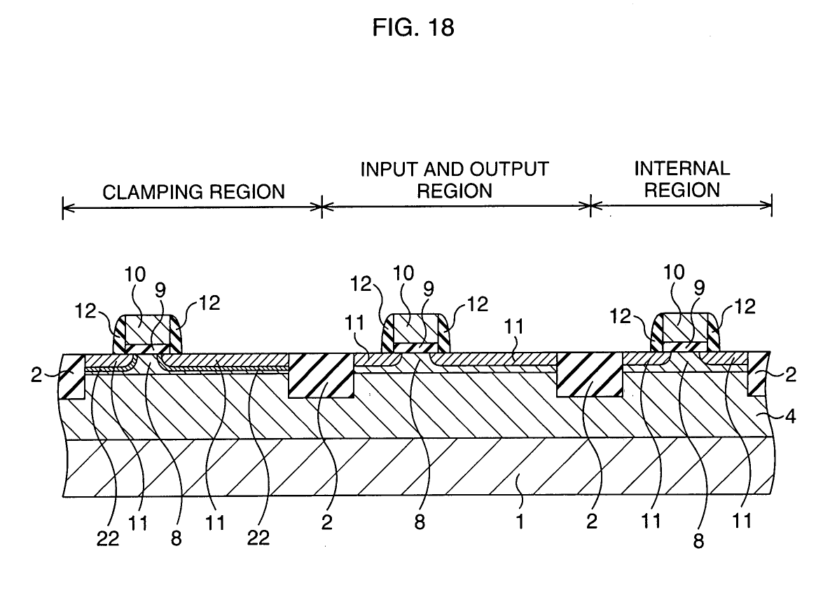

Subsequently, as shown in FIG. 18, after the resist mask 21 is removed after the ion-implantation, an Si oxide film of the thickness of about 130 nm is formed on the entire surface by, for example, a CVD method, and by applying anisotropic etching to the film, side wall spacers 12 are formed at the sides of each of the gate electrodes 10.

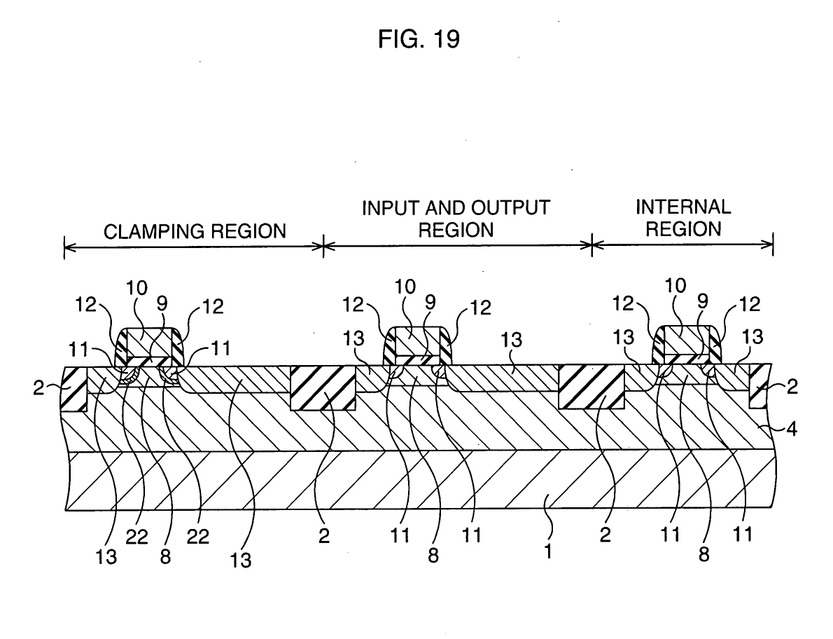

Next, as shown in FIG. 19, n⁺ diffusion layers 13 are formed as in the first embodiment. In formation of the n⁺ diffusion layer 13, for example, phosphorus ion is ion-implanted with the energy of 15 keV and the dose amount of 7×10¹⁵. Further, for example, rapid thermal annealing (RTA) at 1000° C. is performed for about ten seconds under nitrogen atmosphere, whereby the impurities in the n⁻ diffusion layers 11, the n⁺ diffusion layers 13 and the pocket layers 22 are activated. As a result of this, source diffusion layers and drain diffusion layers are formed.

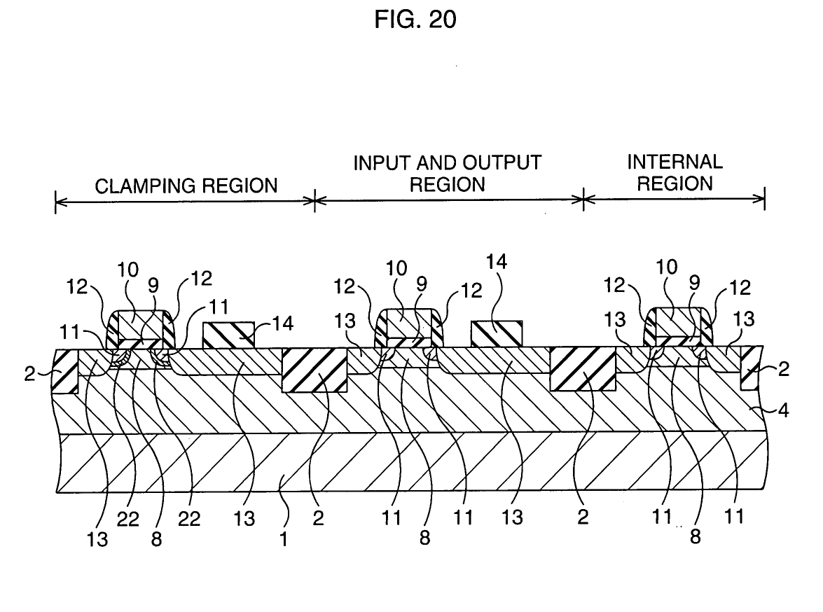

Next, as shown in FIG. 20, silicide blocks 14 are formed on the drain diffusion layers in the clamping region and the input and output region.

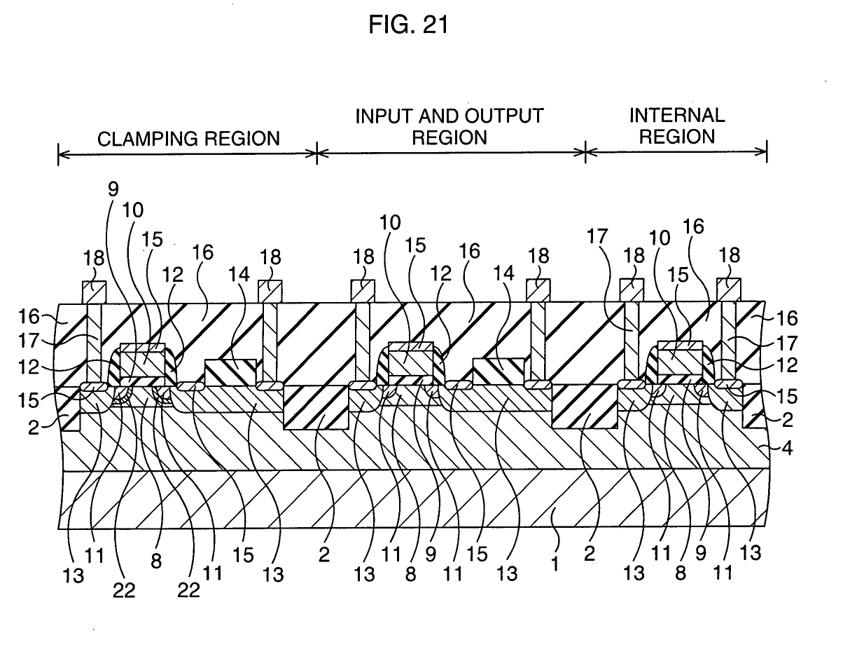

Next, as shown in FIG. 21, silicide layers 15 are formed on the surfaces of the gate electrodes 10 and the n⁺ diffusion layers 13. Subsequently, an interlayer insulation film 16, contact plugs 17 and wirings 18 are formed as in the first embodiment.

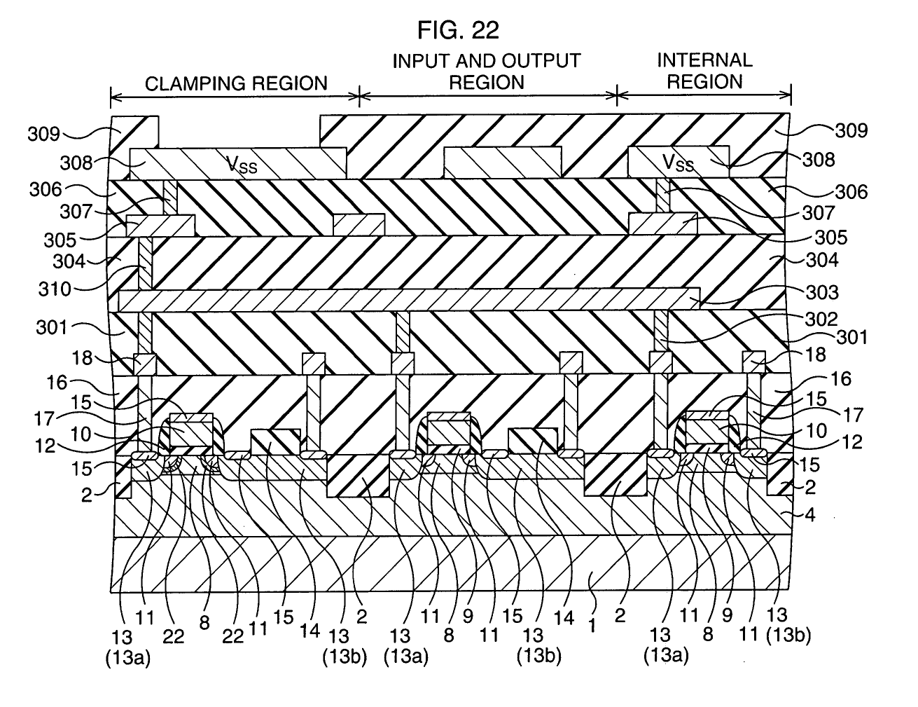

Thereafter, as shown in FIG. 22, an insulation film 301 which covers the wirings 18, contact plugs 302 in the insulation film 301 and connected to the wirings 18, wirings 303 which are connected to the contact plugs 302, an insulation film 304 which covers the wirings 303, contact plugs 310 in the insulation film 304 and connected to the wirings 303, wirings 305 which are connected to the contact plugs 310, an insulation film 306 which covers the wirings 305, contact plugs 307 in the insulation film 306 and connected to the wirings 305, Vss pads 308 which are connected to the contact plugs 307, and an insulation film 309 which covers various kinds of pads including the Vss pads 308 are sequentially formed, and thereby the semiconductor device is completed. In this case, the insulation film 309 is processed so that a part of the surface of the Vss pad 308 is exposed. The source (13a) of each transistor is electrically connected to the Vss pad 308, the drain of the I/O transistor is electrically connected to the I/O pad, and the drain of the power supply clamping transistor is electrically connected to the Vdd pad.

In the semiconductor device according to the second embodiment thus manufactured, the p-type pocket layers 22 with higher concentration than the channel portion is formed. Therefore, junction of the drain ends in the clamping region is sharper than that in the internal region, and the operation starting voltage of the nMOS transistor in the clamping region, namely, the voltage which causes snap-back becomes lower than that of the nMOS transistor in the internal region. Accordingly, the internal circuit is protected as in the first embodiment.

The silicide block 14 may not formed.

-Third Embodiment-

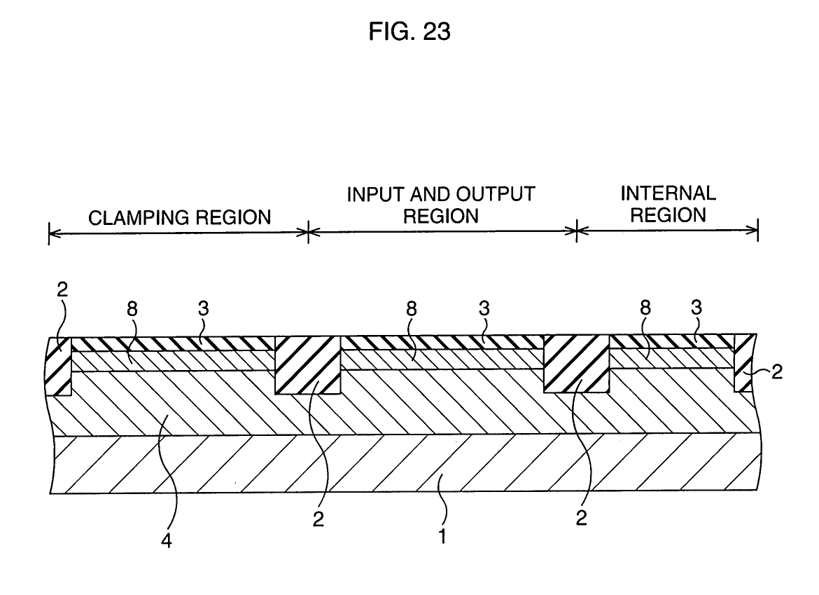

Next, a third embodiment of the present invention will be explained. FIG. 23 to FIG. 31 are sectional views showing a manufacturing method of a semiconductor device according to the third embodiment of the present invention in the order of the process steps. In the present embodiment, nMOS transistors of the gate length of 0.34 μm, the thickness of the gate insulation film of 8 nm and the operating voltage of 3.3 V are also formed in each of the clamping region, the input and output region and the internal region.

In the present embodiment, as shown in FIG. 23, an element isolation insulating film 2 is formed on the surface of an Si substrate 1 by STI first. Next, an Si oxide film 3 of the thickness of about 10 nm, for example, is formed by thermally oxidizing the surface of the Si substrate 1. Next, p-wells 4 are formed as in the first embodiment. In formation of the p-well 4, for example, boron ion is ion-implanted with the energy of 300 keV and the dose amount of 3.0×10¹³, and thereafter boron ion is ion-implanted with the energy of 100 keV and the dose amount of 2.0×10¹². Further, boron ion is ion-implanted with the energy of 30 keV and the dose amount of 5×10¹², and thereby p-wells 8 are formed in the clamping region, the input and output region and the internal region.

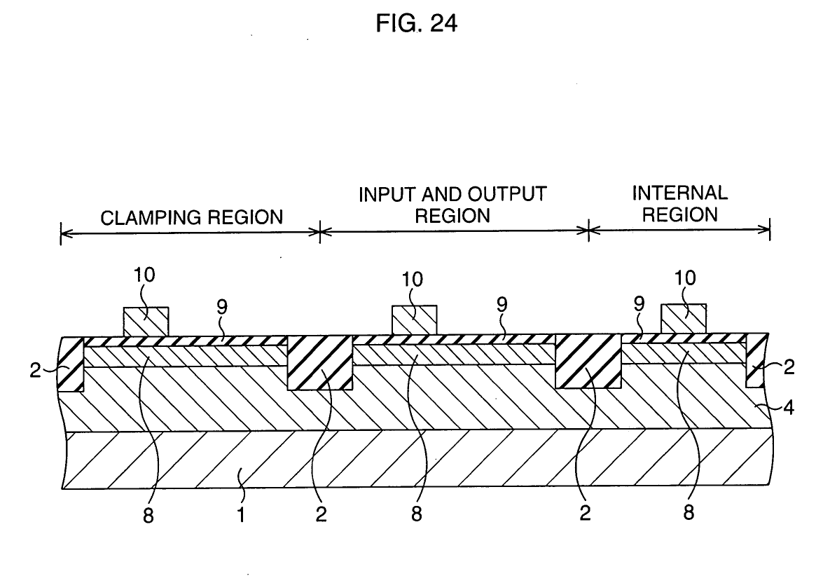

Subsequently, as shown in FIG. 24, after the Si oxide film 3 is removed, thermal oxidation is performed again, and thereby a gate oxide film 9 of the thickness of 8 nm is formed. Next, the gate electrodes 10 are formed as in the first embodiment.

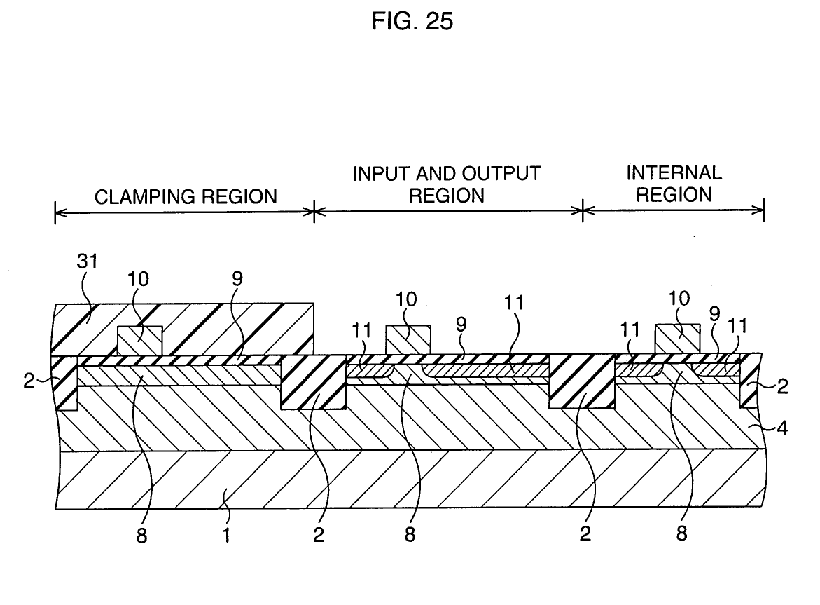

Next, as shown in FIG. 25, a resist mask 31 which exposes the input and output region and the internal region is formed by a photolithography technique. Thereafter, by performing ion implantation of phosphorus ion by using the resist mask 31, n⁻ diffusion layers 11 are formed in the input and output region and the internal region. In formation of the n⁻ diffusion layer 11, for example, phosphorus ion is ion-implanted with the energy of 35 keV and the dose amount of 4×10¹³.

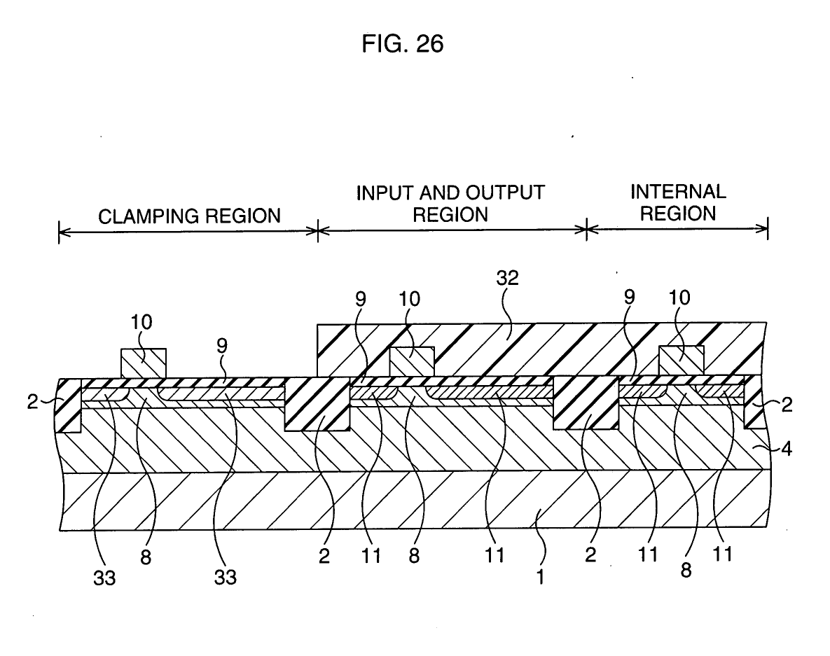

Thereafter, as shown in FIG. 26, after the resist mask 31 is removed, a resist mask 32 which exposes the clamping region is formed by a photolithography technique. Next, by performing ion implantation of arsenic ion by using the resist mask 32, n⁻ diffusion layers 33 are formed in the clamping region. In formation of the n⁻ diffusion layer 33, for example, arsenic ion is ion-implanted with the energy of 3 keV and the dose amount of 8×10¹³.

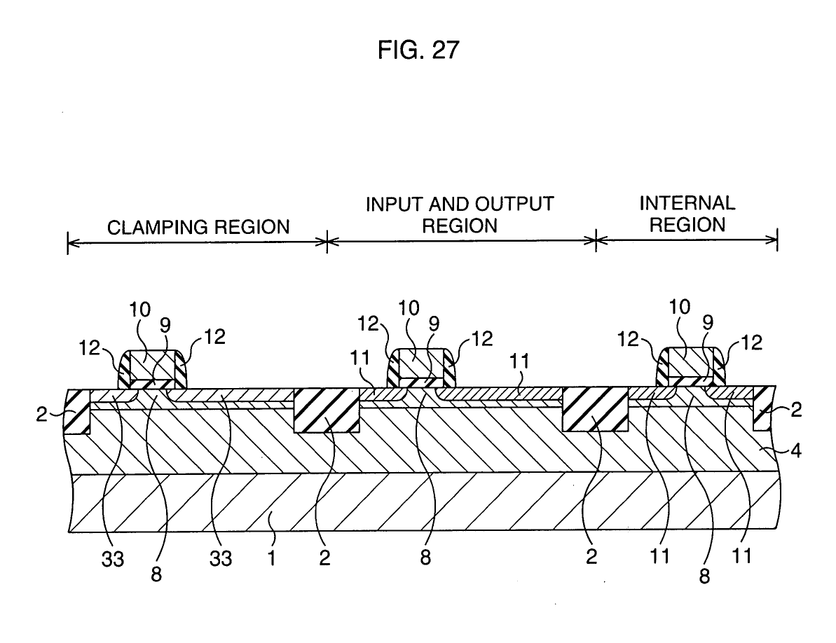

Next, as shown in FIG. 27, after the resist mask 32 is removed, an Si oxide film of the thickness of about 130 nm is formed on the entire surface by, for example, a CVD method, and by applying anisotropic etching to the film, side wall spacers 12 are formed at the sides of each of the gate electrodes 10.

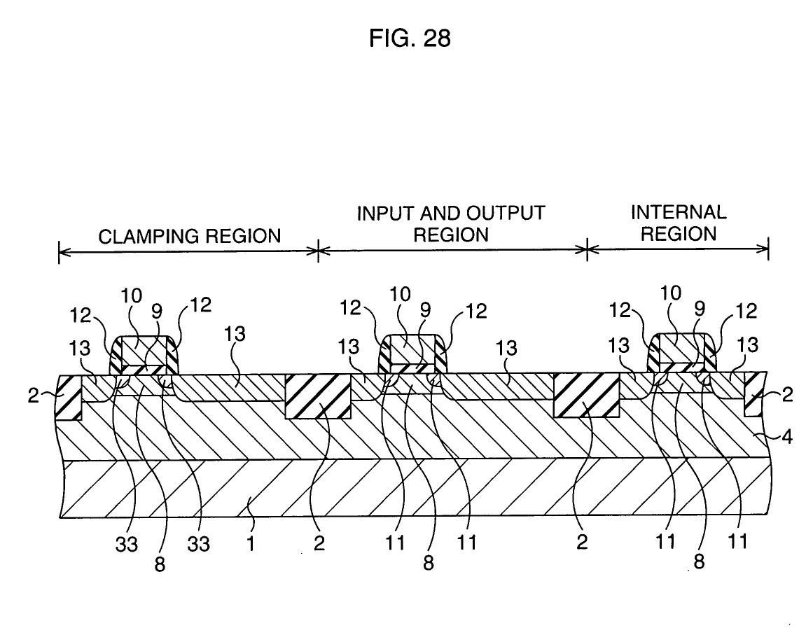

Thereafter, as shown in FIG. 28, an n⁺ diffusion layer 13 is formed as in the first embodiment. In formation of the n⁺ diffusion layer 13, for example, phosphorus ion is ion-implanted with the energy of 15 keV and the dose amount of 7×10¹⁵. Further, for example, rapid thermal annealing (RTA) at 1000° C. is performed for about ten seconds under nitrogen atmosphere, whereby the impurities in the n⁻ diffusion layers (11 and 33) and the n⁺ diffusion layers 13 are activated. As a result of this, source diffusion layers and drain diffusion layers are formed.

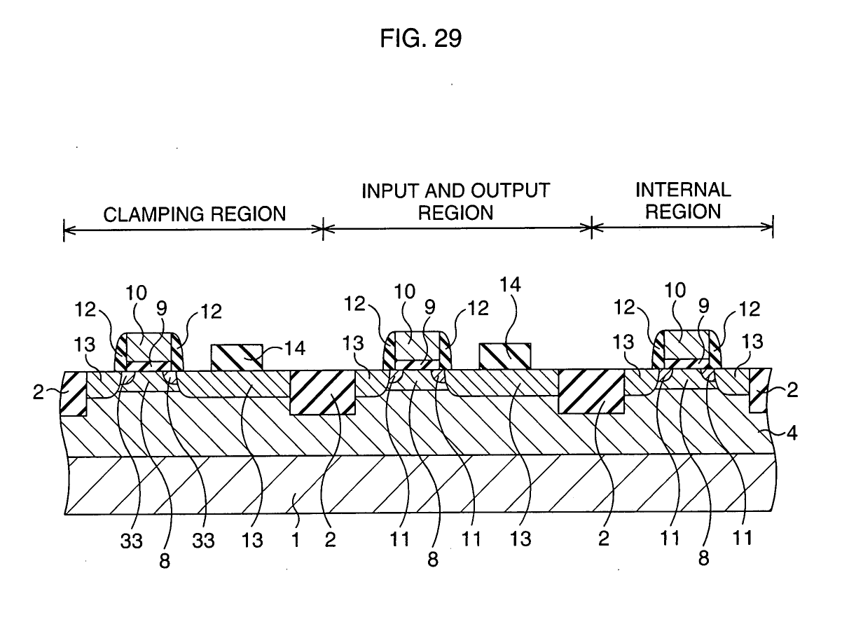

Next, as shown in FIG. 29, silicide blocks 14 are formed on the drain diffusion layers in the clamping region and the input and output region as shown in FIG. 29.

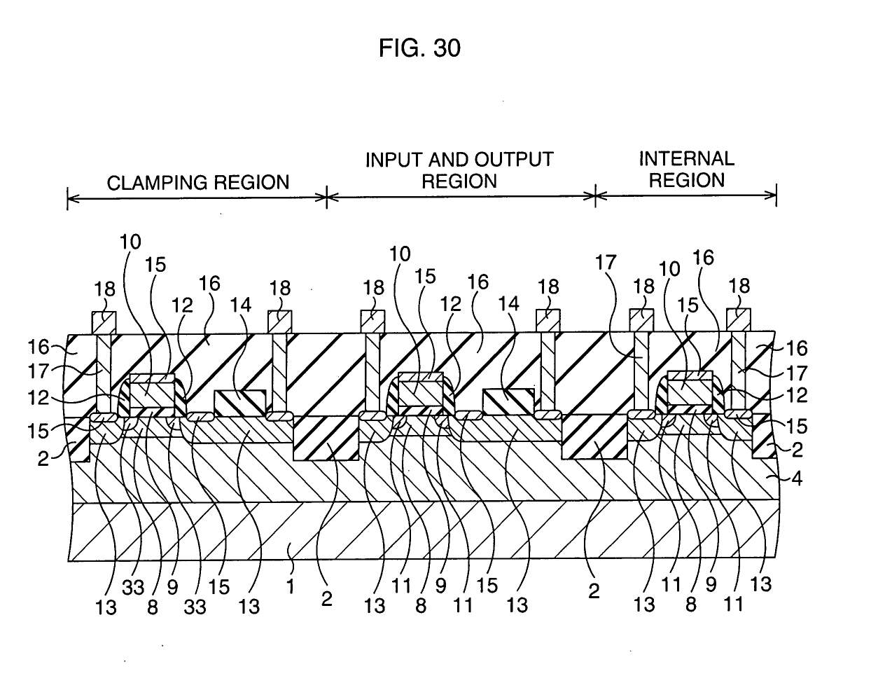

Thereafter, as shown in FIG. 30, silicide layers 15 are formed on the surfaces of the gate electrodes 10 and the n⁺ diffusion layers 13. Subsequently, an interlayer insulation film 16, contact plugs 17 and wirings 18 are formed as in the first embodiment.

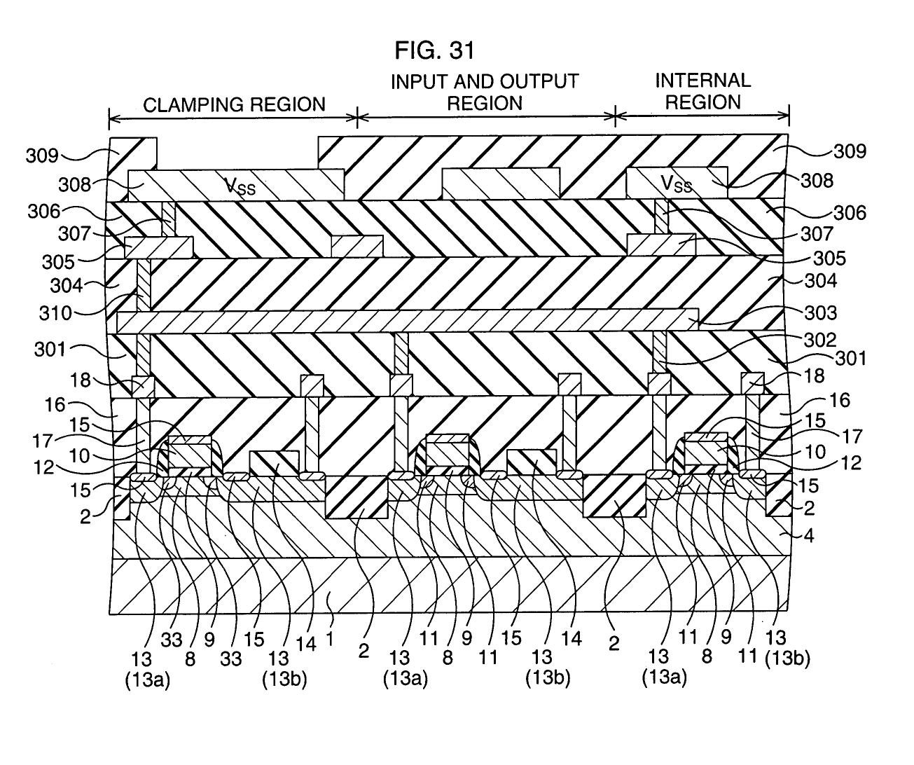

Thereafter, as shown in FIG. 31, an insulation film 301 which covers the wirings 18, contact plugs 302 in the insulation film 301 and connected to the wirings 18, wirings 303 which are connected to the contact plugs 302, an insulation film 304 which covers the wirings 303, contact plugs 310 in the insulation film 304 and connected to the wirings 303, wirings 305 which are connected to the contact plugs 310, an insulation film 306 which covers the wirings 305, contact plugs 307 in the insulation film 306 and connected to the wirings 305, Vss pads 308 which are connected to the contact plugs 307, and an insulation film 309 which covers various kinds of pads including the Vss pads 308 are sequentially formed, and thereby the semiconductor device is completed. In this case, the insulation film 309 is processed so that a part of the surface of the Vss pad 308 is exposed. The source (13a) of each transistor is electrically connected to the Vss pad 308, the drain of the I/O transistor is electrically connected to the I/O pad, and the drain of the power supply clamping transistor is electrically connected to the Vdd pad.

In the semiconductor device according to the third embodiment thus manufactured, the impurity concentration of the n⁻ diffusion layer 33 in the clamping region is higher than the impurity concentration of the n⁻ diffusion layer 11 in the internal region. Therefore, junction of the drain ends in the clamping region is sharper than that in the internal region, and the operation starting voltage of the nMOS transistor in the clamping region, namely, the voltage which causes snap-back becomes lower than that of the nMOS transistor in the internal region. Accordingly, the internal circuit is protected as in the first embodiment.

The silicide block 14 may not be formed.

-Fourth Embodiment-

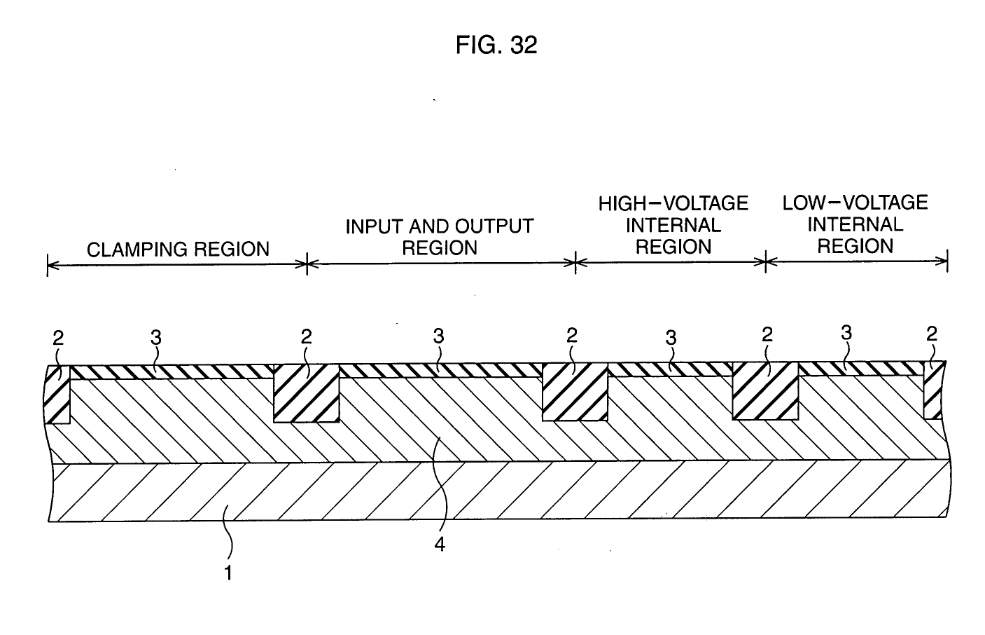

Next, a fourth embodiment of the present invention will be explained. FIG. 32 to FIG. 45 are sectional views showing a manufacturing method of a semiconductor device according to the fourth embodiment of the present invention in the order of the process steps. In FIG. 32 to FIG. 45, a region in the internal region in which an nMOS transistor of the operating voltage of 3.3 V is formed, and a region in the internal region in which an nMOS transistor of the operating voltage of 1.2 V is formed are shown. The regions will be called a high-voltage internal region and a low-voltage internal region for convenience, hereinafter. In the present embodiment, nMOS transistors of the gate length of 0.34 μm, the thickness of the gate insulation film of 8 nm and the operating voltage of 3.3 V are formed in each of the clamping region, the input and output region and the high-voltage internal region, and an nMOS transistor of the gate length of 0.11 μm, the thickness of the gate insulation film of 1.8 nm and the operating voltage of 1.2 V is formed in the low-voltage internal region.

In the present embodiment, as shown in FIG. 32, an element isolation insulating film 2 is formed on the surface of an Si substrate 1 by STI first. Next, an Si oxide film 3 of the thickness of about 10 nm, for example, is formed by thermally oxidizing the surface of the Si substrate 1. Next, p-wells 4 are formed as in the first embodiment. In formation of the p-well 4, for example, boron ion is ion-implanted with the energy of 300 keV and the dose amount of 3.0×10¹³, and thereafter boron ion is ion-implanted with the energy of 100 keV and the dose amount of 2.0×10¹².

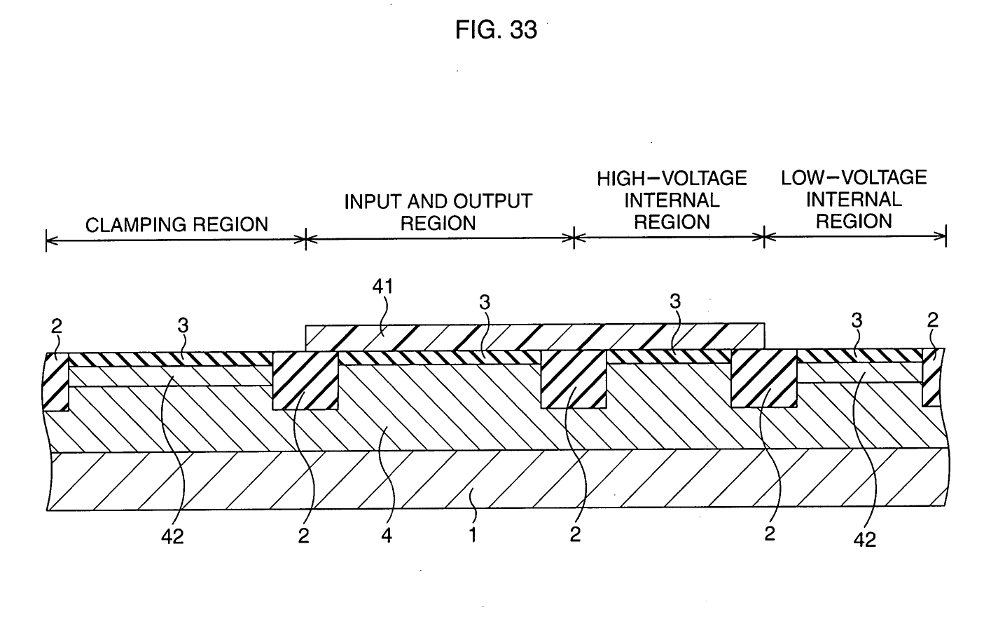

Subsequently, as shown in FIG. 33, a resist mask 41 which exposes the clamping region and the low-voltage internal region is formed by a photolithography technique. Next, p-wells 42 are formed in the clamping region and the low-voltage internal region by ion-implanting boron ion with the energy of 10 keV and the dose amount of 4.5×10¹² by using the resist mask 41. The p-well 42 may be formed in only the low-voltage internal region.

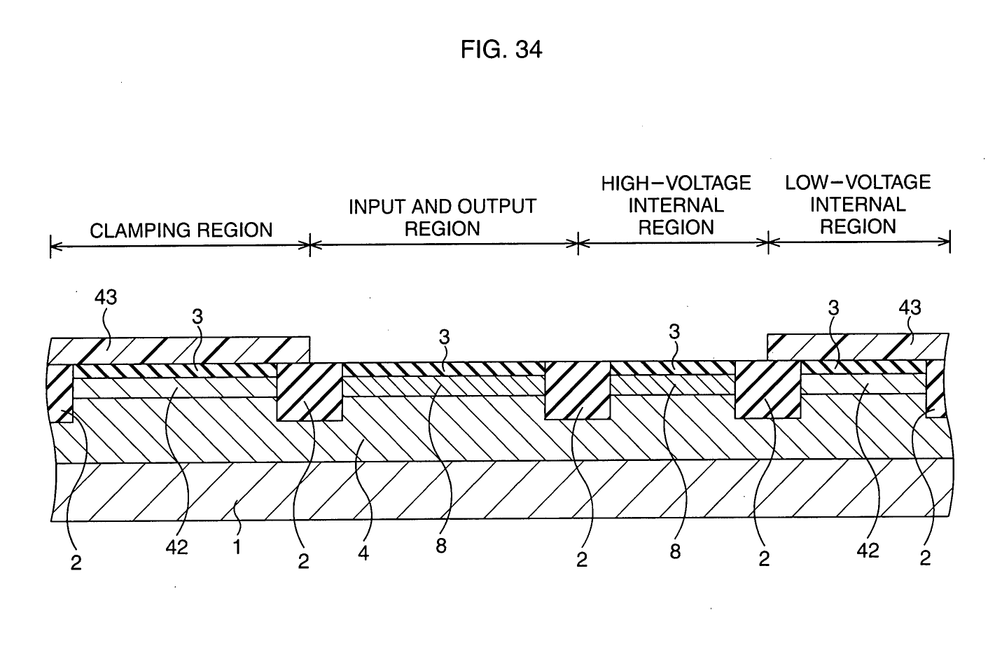

Next, as shown in FIG. 34, after the resist mask 41 is removed, a resist mask 43 which exposes the input and output region and the high-voltage internal region is formed by a photolithography technique. Subsequently, by using the resist mask 43, boron ion is ion-implanted with the energy of 30 keV and the dose amount of 5×10¹², and thereby p-wells 8 are formed in the input and output region and the high-voltage internal region. The clamping region may be exposed from the resist mask 43, and ion implantation may be simultaneously performed in the clamping region.

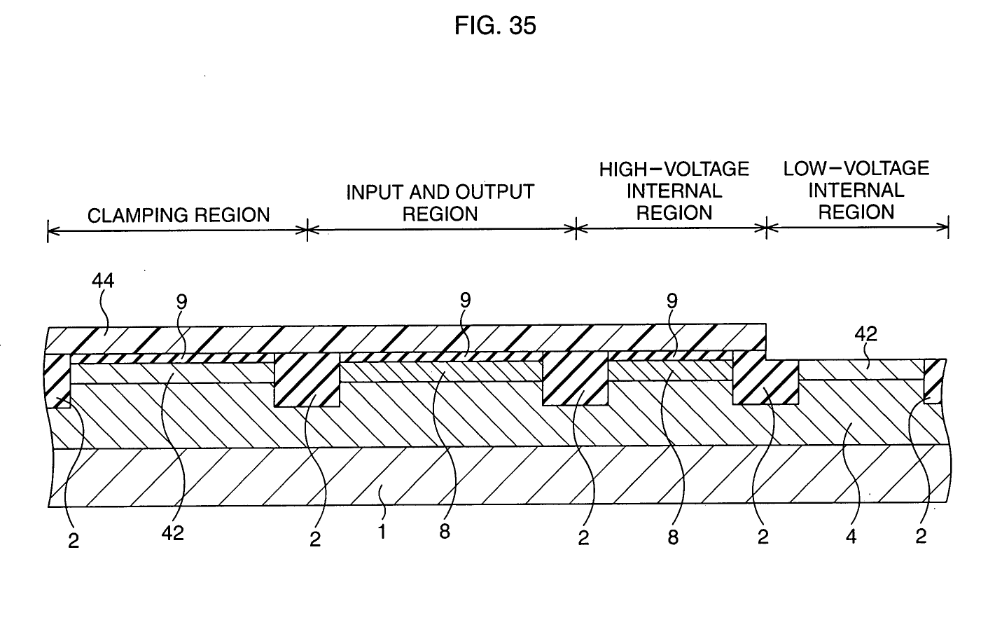

Next, as shown in FIG. 35, after the resist mask 43 is removed, the Si oxide film 3 is removed. Next, thermal oxidation is performed again, and thereby a gate oxide film 9 of the thickness of 7.2 nm is formed. Thereafter, a resist mask 44 which exposes the low-voltage internal region is formed by a photolithography technique. Subsequently, the gate oxide film 9 in the low-voltage internal region is removed by using the resist mask 44.

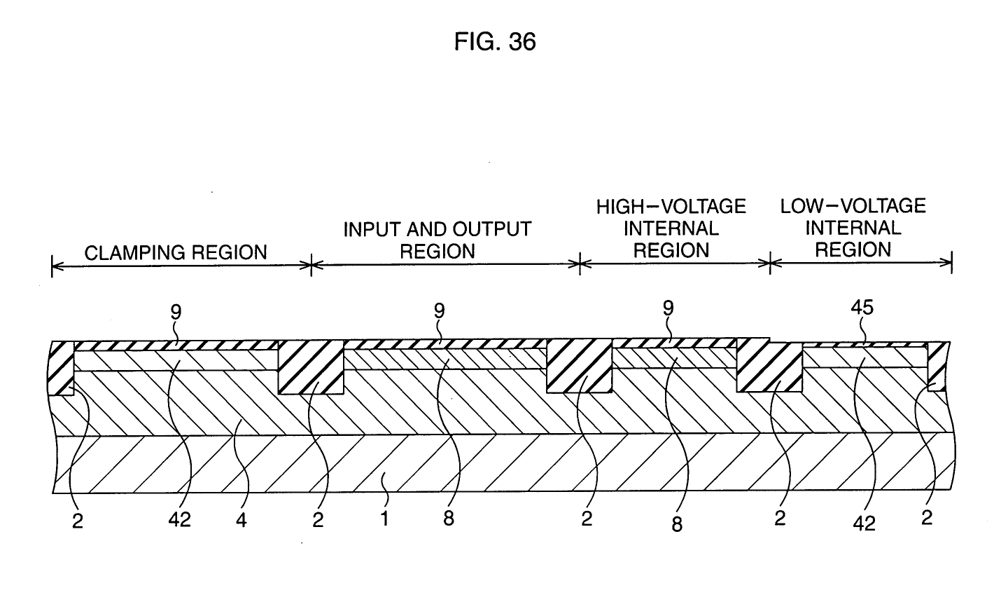

Next, as shown in FIG. 36, after the resist mask 44 is removed, thermal oxidation is performed again, whereby a gate oxide film 45 of the thickness of 1.8 nm is formed in the low-voltage internal region, and the gate oxide film 9 is made as thick as 8 nm.

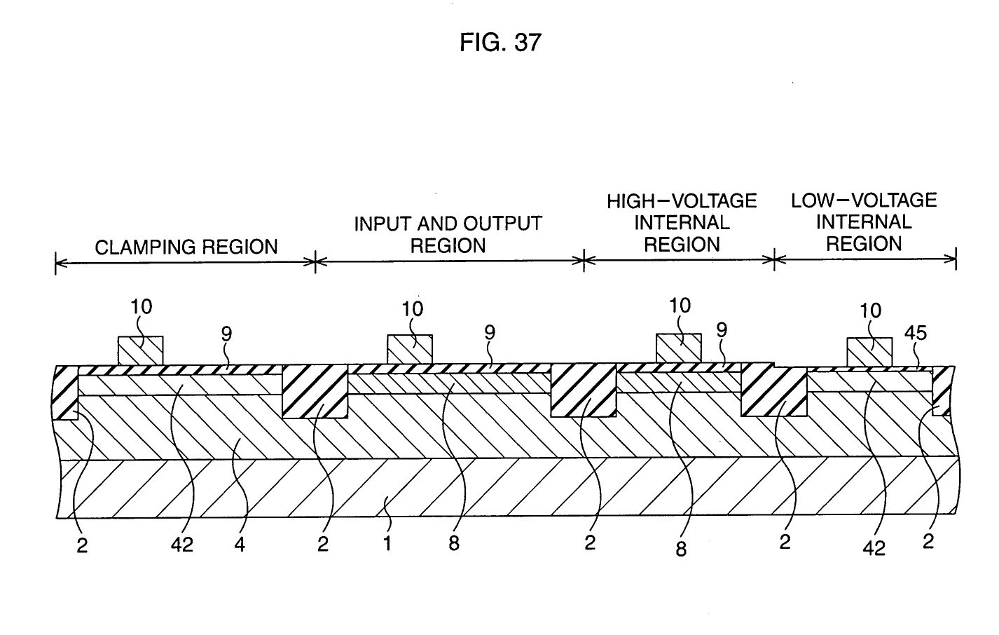

Thereafter, as shown in FIG. 37, gate electrodes 10 are formed as in the first embodiment.

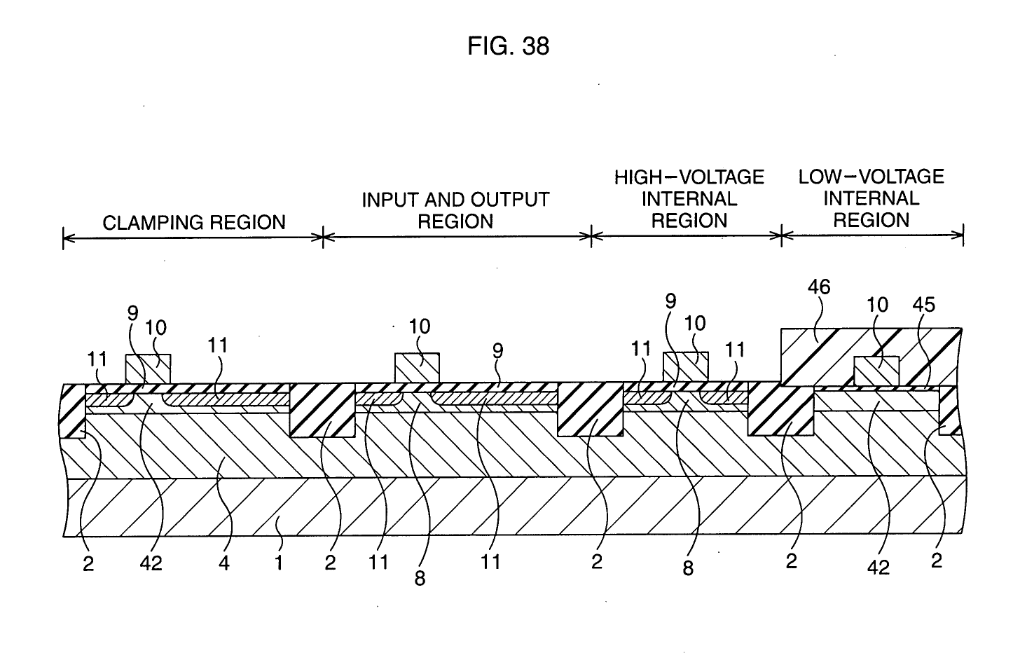

Subsequently, as shown in FIG. 38, a resist mask 46 which exposes the clamping region, the input and output region, and the high-voltage internal region is formed by a photolithography technique. Next, n⁻ diffusion layers 11 are formed in the clamping region, the input and output region and the high-voltage internal region as in the first embodiment. In formation of the n⁻ diffusion layer 11, for example, phosphorus ion is ion-implanted with the energy of 35 keV and the dose amount of 4×10¹³. The n⁻ diffusion layer 11 may not be formed in the clamping region.

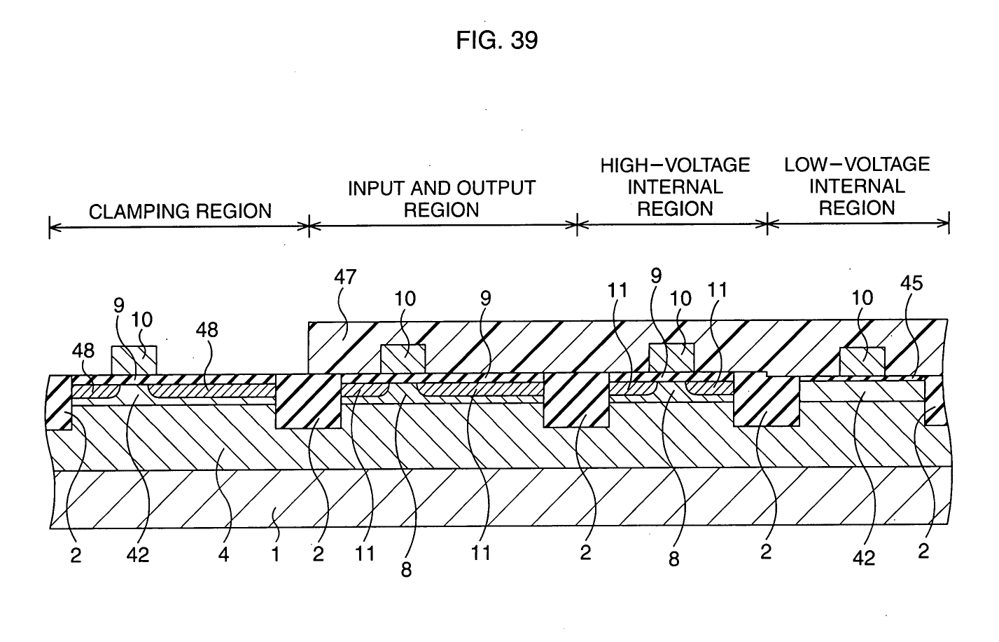

Next, as shown in FIG. 39, after the resist mask 46 is removed, a resist mask 47 which exposes the clamping region is formed by a photolithography technique. Thereafter, n⁻ diffusion layers 48 are formed in the clamping region by using the resist mask 47. In formation of the n⁻ diffusion layer 48, for example, phosphorus ion is ion-implanted with the energy of 30 keV and the dose amount of 1.3×10¹⁴. Depending on the operation start voltage and the junction leak in the clamping region, formation of the n⁻ diffusion layer 48 may be omitted. Namely, formation of the n⁻ diffusion layer 48 is performed to restrain the junction from being too sharp to ion-implant arsenide later, and is not always necessary.

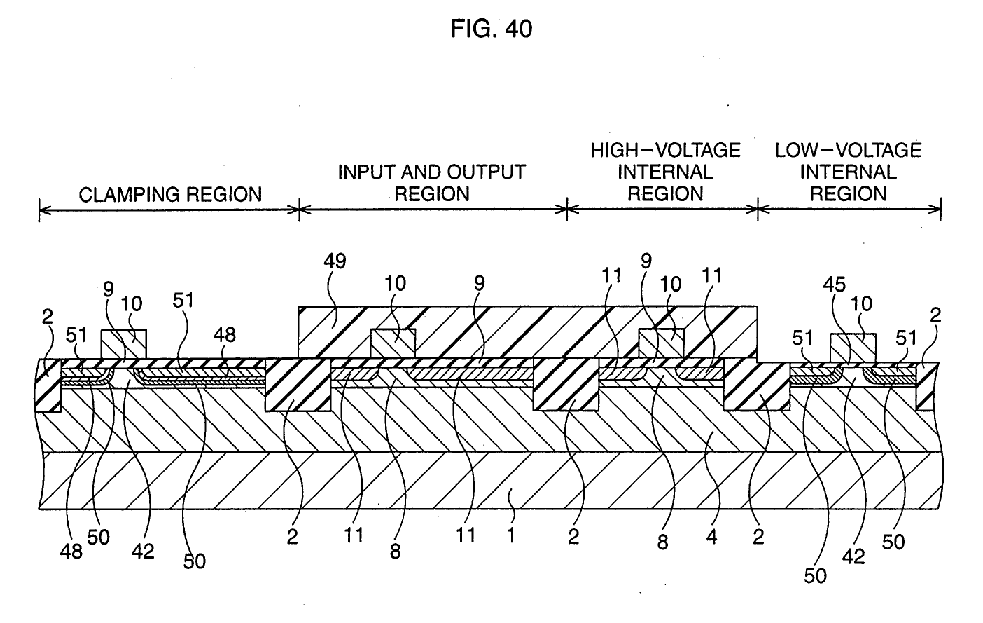

Subsequently, as shown in FIG. 40, after the resist mask 47 is removed, a resist mask 49 which exposes the clamping region and the low-voltage internal region is formed by a photolithography technique. Next, pocket layers 50 and n⁻ diffusion layers 51 are formed in the clamping region and the low-voltage internal region. In formation of the pocket layer 50, BF₂ ion is implanted with the energy of 35 keV and the dose amount of 1×10¹³, for example, from the direction inclined 10° to 45° from the perpendicular direction to the surface of the Si substrate 1. In formation of the n⁻ diffusion layer 51, for example, arsenide ion is ion-implanted with the energy of 3 keV and the dose amount of 1×10¹⁵.

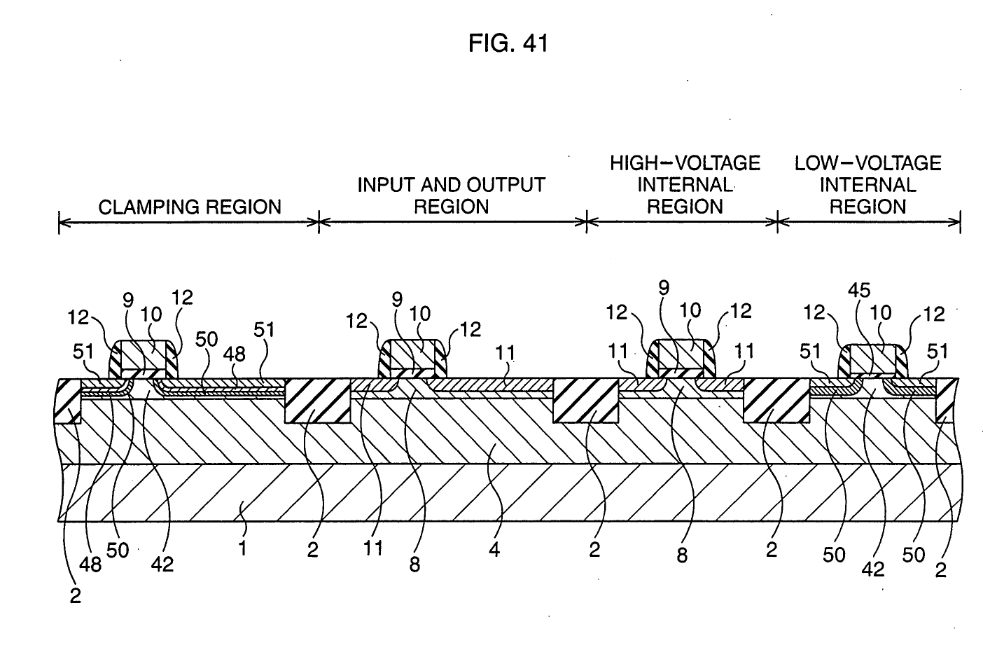

Next, as shown in FIG. 41, after the resist mask 49 is removed, an Si oxide film of the thickness of about 130 nm is formed on the entire surface by a CVD method, for example, and anisotropic etching is applied to the film, whereby side wall spacers 12 are formed at the sides of each of the gate electrodes 10.

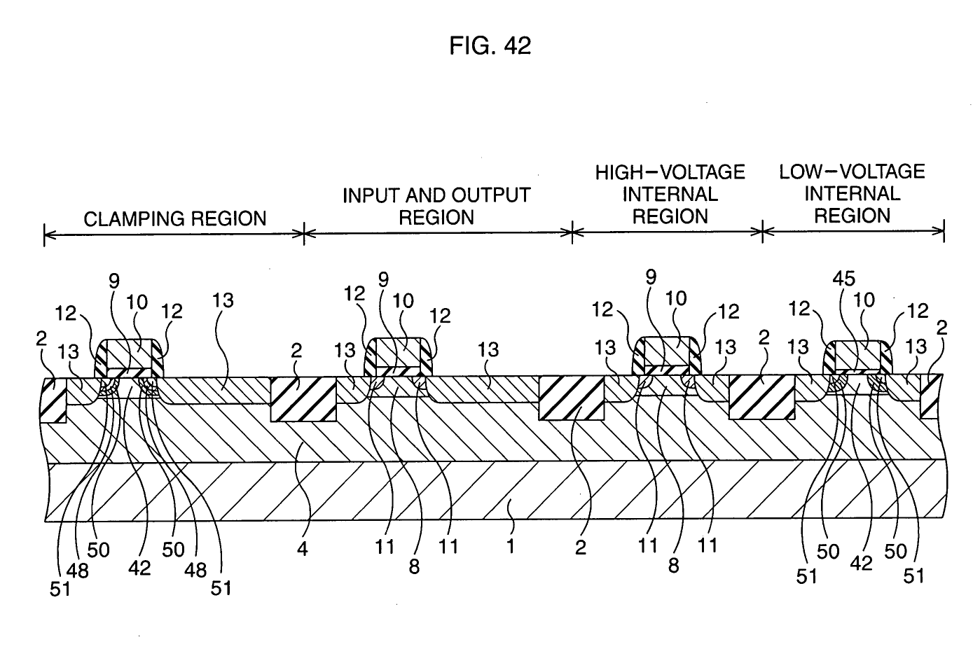

Thereafter, as shown in FIG. 42, n⁺ diffusion layers 13 are formed as in the first embodiment. In formation of the n⁺ diffusion layer 13, for example, phosphorus ion is ion-implanted with the energy of 15 keV and the dose amount of 7×10¹⁵. Further, the impurities in each of the diffusion layers are activated by performing rapid thermal annealing (RTA) at 1000° C. for ten seconds under nitrogen atmosphere. As a result, source diffusion layers and drain diffusion layers are formed.

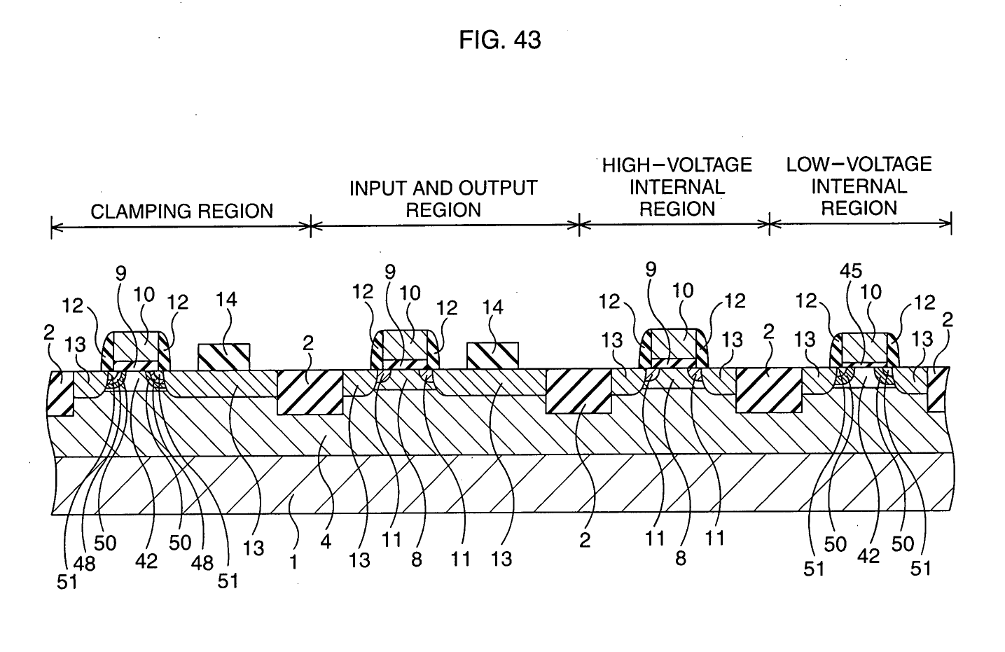

Next, as shown in FIG. 43, silicide blocks 14 are formed on the drain diffusion layers in the clamping region and the input and output region as in the first embodiment.

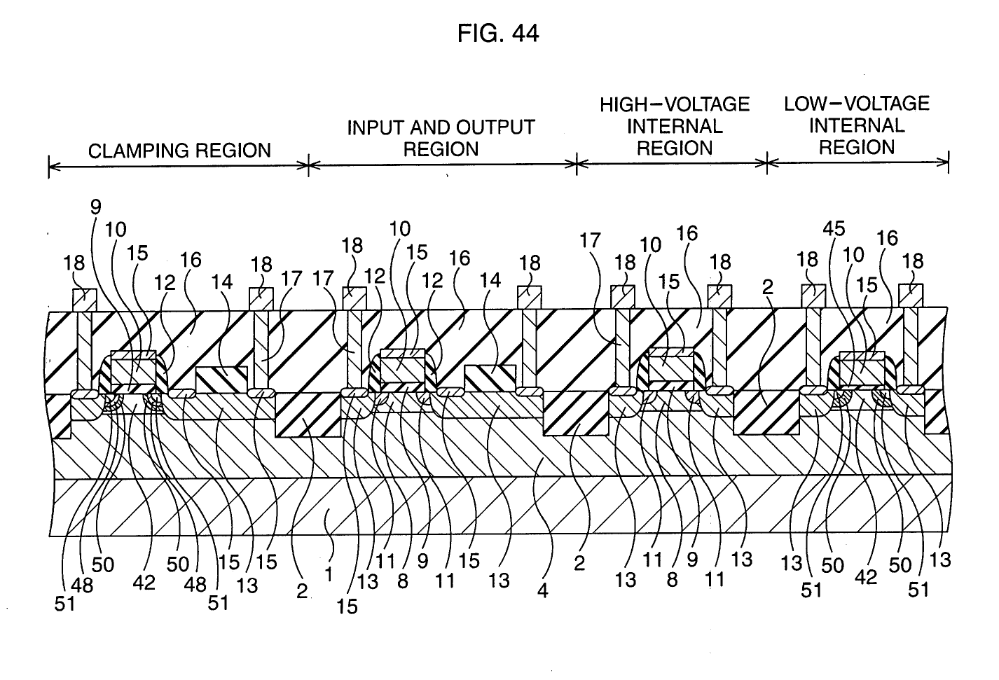

Thereafter, as shown in FIG. 44, silicide layers 15 are formed on the surfaces of the gate electrodes 10 and the n⁺ diffusion layer 13. Subsequently, as in the first embodiment, an interlayer insulation film 16, contact plugs 17 and wirings 18 are formed.

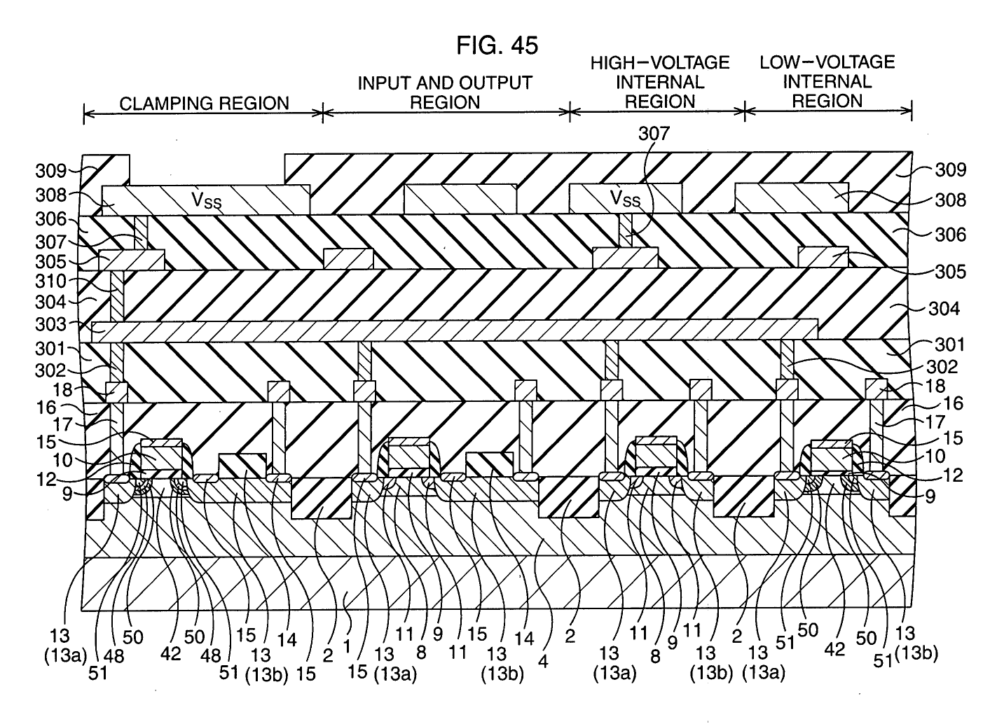

Thereafter, as shown in FIG. 45, an insulation film 301 which covers the wirings 18, contact plugs 302 in the insulation film 301 and connected to the wirings 18, wirings 303 which are connected to the contact plugs 302, an insulation film 304 which covers the wirings 303, contact plugs 310 in the insulation film 304 and connected to the wirings 303, wirings 305 which are connected to the contact plugs 310, an insulation film 306 which covers the wirings 305, contact plugs 307 in the insulation film 306 and connected to the wirings 305, Vss pads 308 which are connected to the contact plugs 307, and an insulation film 309 which covers various kinds of pads including the Vss pads 308 are sequentially formed, and thereby the semiconductor device is completed. In this case, the insulation film 309 is processed so that a part of the surface of the Vss pad 308 is exposed. The source (13a) of each transistor is electrically connected to the Vss pad 308, the drain of the I/O transistor is electrically connected to the I/O pad, and the drain of the power supply clamping transistor is electrically connected to the Vdd pad.

In the semiconductor device according to the fourth embodiment thus manufactured, the pocket layer 50 of the same conductivity type (p-type) as the channel is formed, and the impurity concentration of the drain in the clamping region is higher than the impurity concentration of the drain in the internal region. Therefore, junction of the drain ends in the clamping region is sharper than that in the internal region, and the operation starting voltage of the nMOS transistor in the clamping region, namely, the voltage which causes snap-back becomes lower than that of the nMOS transistor in the internal region. Accordingly, the internal circuit is protected as in the first embodiment.

The silicide block 14 may not be formed.

When an nMOS transistor operating at high voltage and an nMOS transistor operating at low voltage are formed in the internal circuit, the increase in the number of steps can be extremely suppressed.

-Fifth Embodiment-

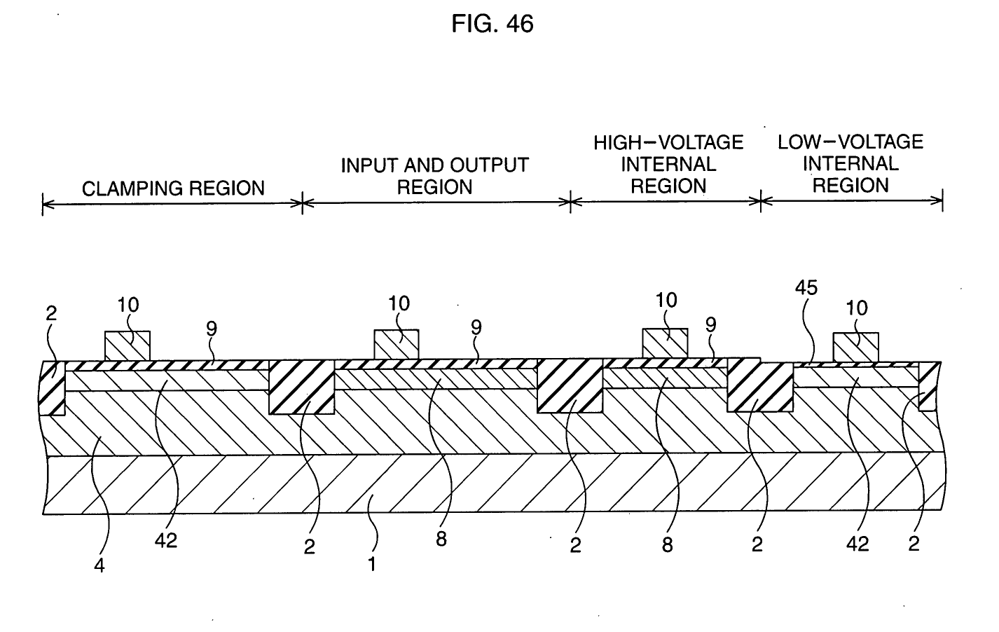

Next, a fifth embodiment of the present invention will be explained. FIG. 46 to FIG. 53 are sectional views showing the manufacturing method of the semiconductor device according to the fifth embodiment of the present invention in the order of the process steps. In the present embodiment, nMOS transistors of the gate length of 0.34 μm, the thickness of the gate insulation film of 8 nm and the operating voltage of 3.3 V are formed in each of the clamping region, the input and output region and the high-voltage internal region, and an nMOS transistor of the gate length of 0.11 μm, the thickness of the gate insulation film of 1.8 nm and the operating voltage of 1.2 V is formed in the low-voltage internal region.

In the present embodiment, as shown in FIG. 46, the process steps up to the formation of the gate electrodes 10 are performed first as in the fourth embodiment.

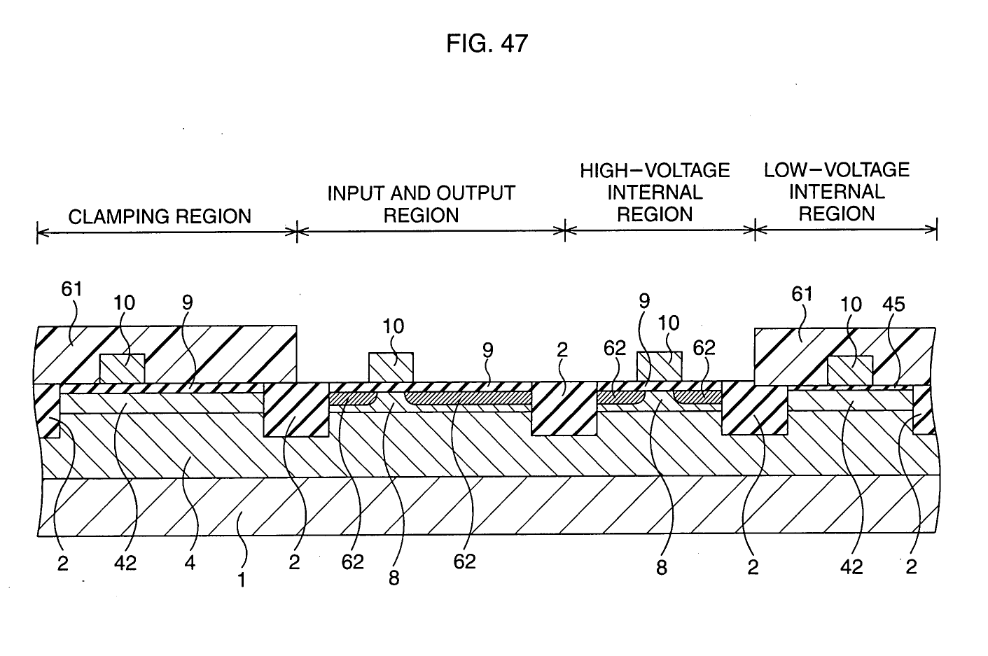

Next, as shown in FIG. 47, a resist mask 61 which exposes the input and output region and the high-voltage internal region is formed by a photolithography technique. Next, n⁻ diffusion layers 62 are formed by using the resist mask 61. In formation of the n⁻ diffusion layer 62, phosphorus ion is implanted with the energy of 35 keV and the dose amount of 1×10¹³ from the direction inclined 20° to 45° from the perpendicular direction to the surface of the Si substrate 1, for example.

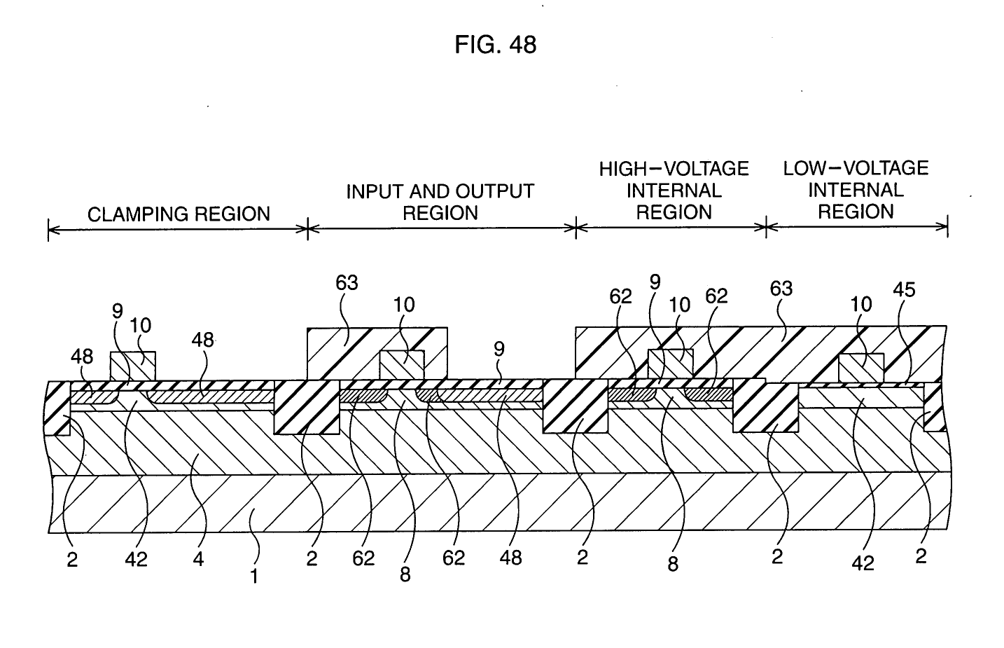

Thereafter, as shown in FIG. 48, after the resist mask 61 is removed, a resist mask 63 which exposes the region in the input and output region in which drains are to be formed and the clamping region is formed by a photolithography technique. Subsequently, n⁻ diffusion layers 48 are formed in the input and output region and the clamping region by using the resist mask 63. In formation of the n⁻ diffusion layer 48, for example, phosphorus ion is ion-implanted with the energy of 30 keV and the dose amount of 1.3×10¹⁴.

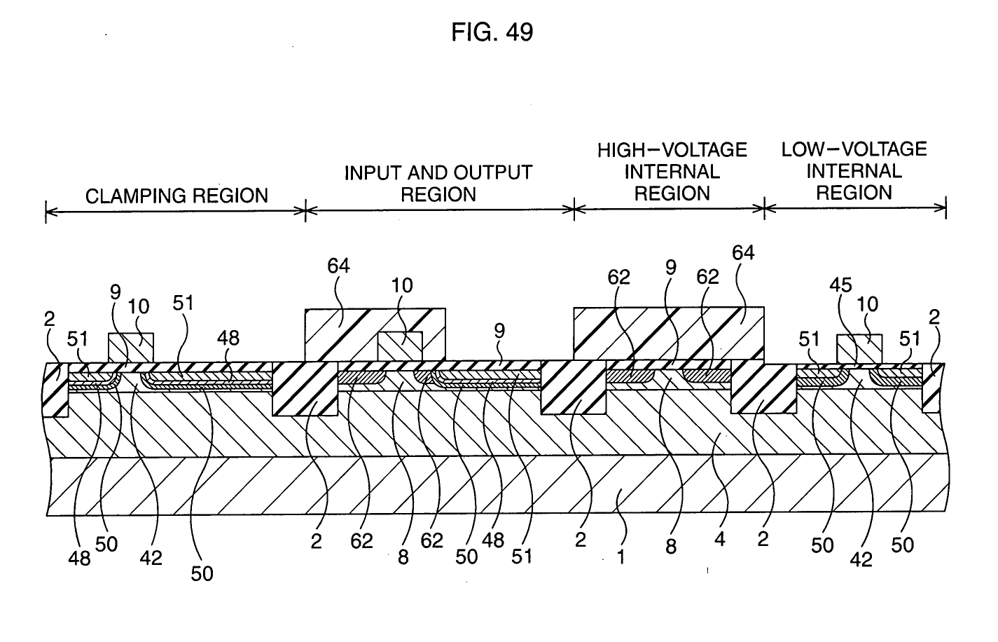

Next, as shown in FIG. 49, after the resist mask 63 is removed, a resist mask 64 which exposes the region in the input and output region in which the drain are to be formed, the clamping region and the low-voltage internal region is formed by a photolithography technique. Next, by using the resist mask 64, pocket layers 50 and n⁻ diffusion layers 51 are formed in the clamping region, the input and output region and the low-voltage internal region. In formation of the pocket layer 50, BF₂ ion is implanted with the energy of 35 keV and the dose amount of 1×10¹³ from the direction inclined 10° to 45° from the perpendicular direction to the surface of the Si substrate 1, for example. In formation of the n⁻ diffusion layer 51, for example, arsenide ion is ion-implanted with the energy of 3 keV and the dose amount of 1×10¹⁵.

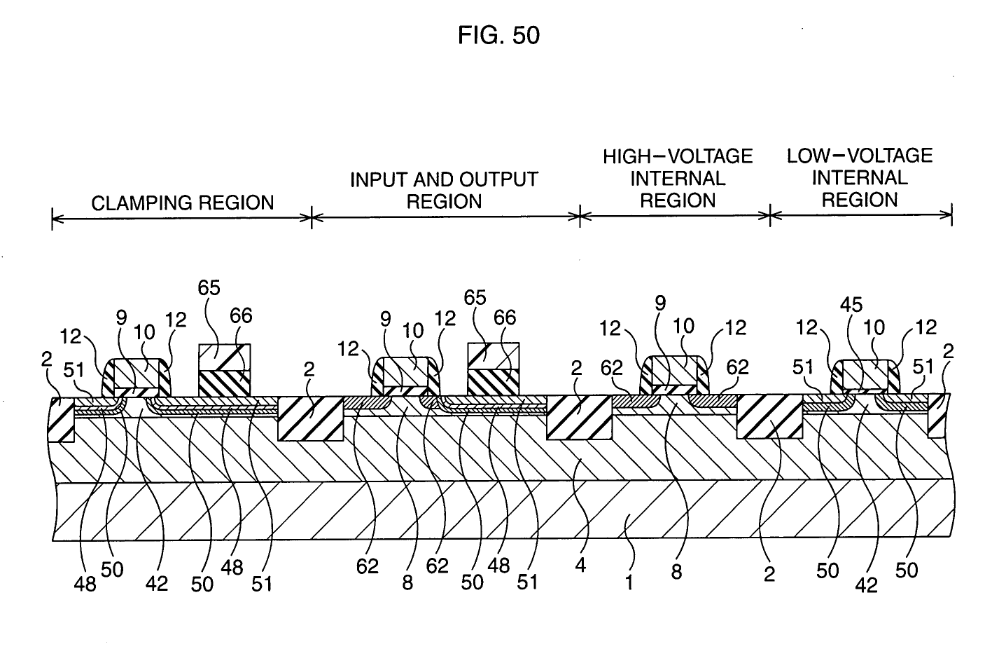

Thereafter, as shown in FIG. 50, after the resist mask 64 is removed, an Si oxide film of the thickness of about 130 nm is formed on the entire surface by, for example, a CVD method. Subsequently, a resist mask 65 which covers only the regions in which silicide blocks are to be formed on the Si oxide film is formed by a photolithography technique. By performing anisotropic etching for the Si oxide film, side wall spacers 12 are formed at the sides of each of the gate electrodes 10, and silicide blocks 66 are formed.

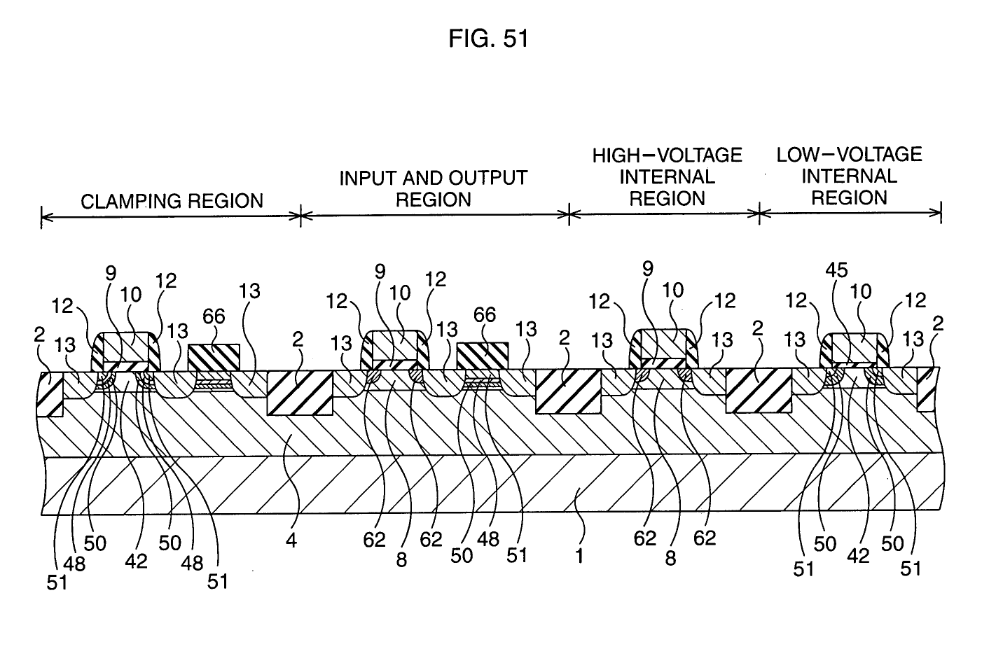

Next, as shown in FIG. 51, after the resist mask 65 is removed, n⁺ diffusion layers 13 are formed as in the first embodiment. In this case, in regions in surface of the n⁻ diffusion layer 51 where the silicide blocks 66 are formed, the n⁺ diffusion layer 13 is not formed. In formation of the n⁺ diffusion layer 13, for example, phosphorus ion is ion-implanted with the energy of 15 keV and the dose amount of 7×10¹⁵. Further, by performing rapid thermal annealing (RTA) at 1000° C. for ten seconds under nitrogen atmosphere, the impurities in each of the diffusion layers are activated. As a result, source diffusion layers and drain diffusion layers are formed.

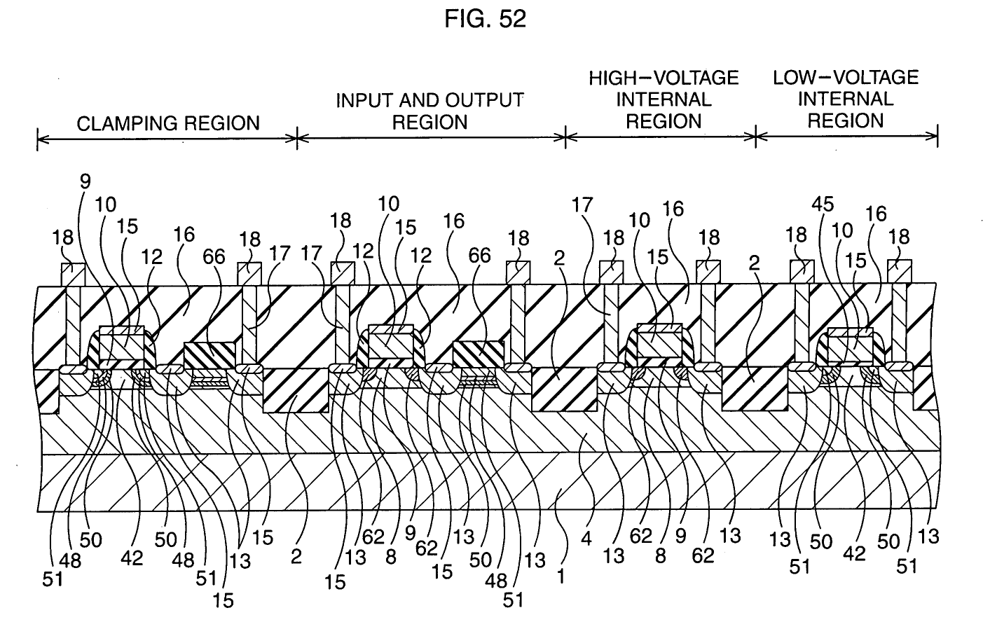

Next, as shown in FIG. 52, silicide layers 15 are formed on the surfaces of the gate electrodes 10 and the n⁺ diffusion layers 13. Subsequently, as in the first embodiment, an interlayer insulation film 16, contact plugs 17 and wirings 18 are formed.

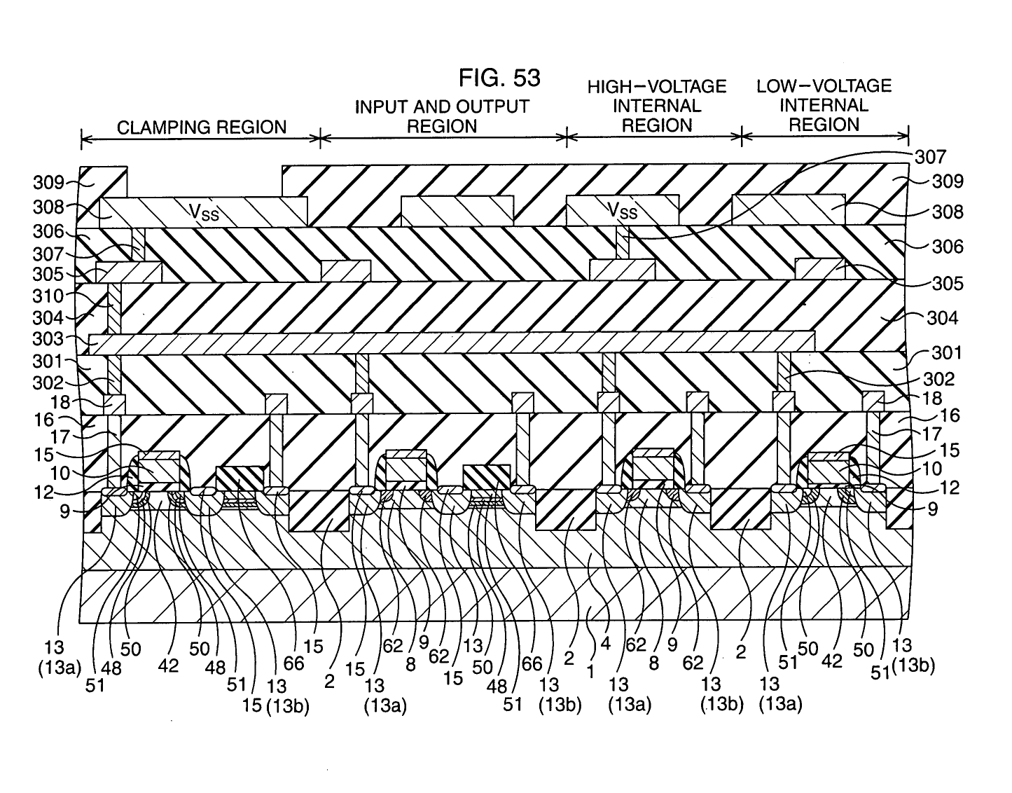

Thereafter, as shown in FIG. 53, an insulation film 301 which covers the wirings 18, contact plugs 302 in the insulation film 301 and connected to the wirings 18, wirings 303 which are connected to the contact plugs 302, an insulation film 304 which covers the wirings 303, contact plugs 310 in the insulation film 304 and connected to the wirings 303, wirings 305 which are connected to the contact plugs 310, an insulation film 306 which covers the wirings 305, contact plugs 307 in the insulation film 306 and connected to the wirings 305, Vss pads 308 which are connected to the contact plugs 307, and an insulation film 309 which covers various kinds of pads including the Vss pads 308 are sequentially formed, and thereby the semiconductor device is completed. In this case, the insulation film 309 is processed so that a part of the surface of the Vss pad 308 is exposed. The source (13a) of each transistor is electrically connected to the Vss pad 308, the drain of the I/O transistor is electrically connected to the I/O pad, and the drain of the power supply clamping transistor is electrically connected to the Vdd pad.

In the semiconductor device according to the fifth embodiment thus manufactured, the same effect as in the fourth embodiment is obtained. The n⁺ diffusion layer is not formed under the silicide blocks 66, and therefore sharper junction is obtained, thus making it possible to protect the internal circuit more reliably.

In each of the embodiments explained above, the dose amount of each of ion implantations for forming the same conductivity type and the inverse conductivity type impurities regions as and from the semiconductor substrate is shown, but this is only one example. Proper combination of the respective embodiments can be considered, but it should be basically determined so that both the operation starting voltage of the parasitic bipolar transistor and the leak current flowing through the power supply clamp at the time of a normal operation have desired values.

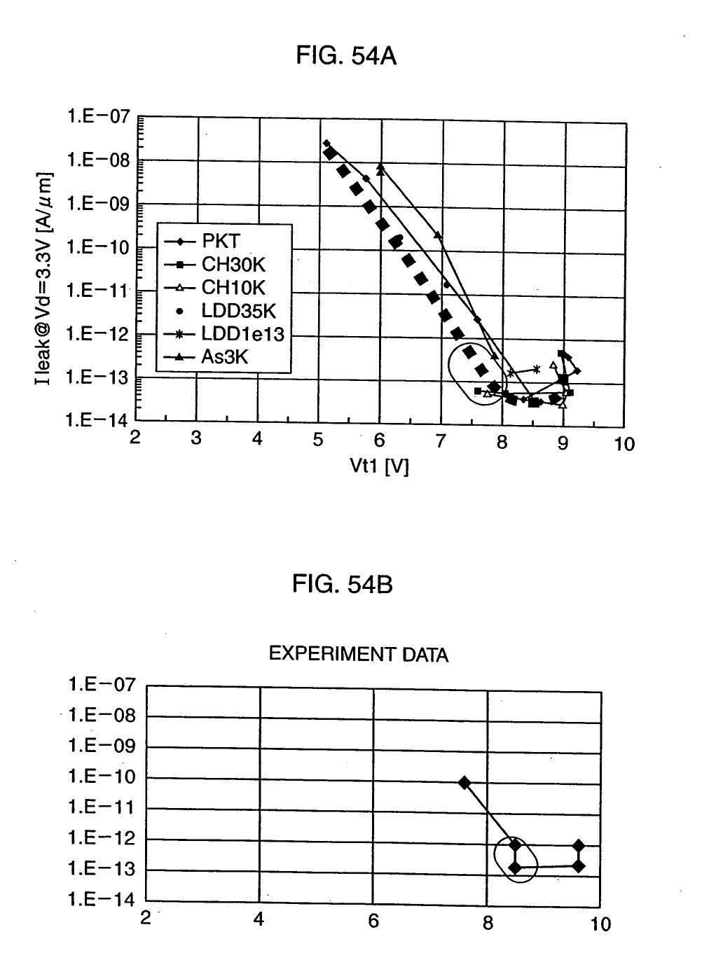

Process condition dependence obtained by a device simulation in the structures and the production methods according to the first to the third embodiments is shown in FIG. 54A. An actual measurement characteristics obtained from a TLP measurement of an actual wafer in the structure according to the fifth embodiment are shown in FIG. 54B. Each condition of the simulation is shown in Table 1, and each condition of the actual measurement is shown in Table 2. FIGS. 54A and 54B both show the same characteristics. Here, the vicinity of the region encircled by the ellipse in each of the drawings is the region where a leak current is small and the operation starting voltage (Vt1) becomes low, and it is suitable to select the process condition with such characteristics.

TABLE 1
SIMULATION CONDITION

| PKT | CH30K | CH10K | LDD35K | LDD1e13 | As + 3K |
|---|---|---|---|---|---|
| SECOND | FIRST | FIRST | THIRD | THIRD | THIRD |
| EMBODIMENT | EMBODIMENT | EMBODIMENT | EMBODIMENT | EMBODIMENT | EMODIMENT |
| BF₂ + 35K | B + 30K | B + 30K5.2e12& | P + 35K | P + 1e13 | |
| | | B + 10K | | | |
| NONE | 5.20E+12 | 1.00E+12 | 1.00E+13 | 35K | 1.07E+15 |
| 1.00E+12 | 1.00E+13 | 5.00E+12 | 5.00E+13 | 20K | 5.00E+14 |
| 5.00E+12 | 5.00E+13 | 1.00E+13 | 1.00E+14 | 10K | 1.00E+14 |
| 6.00E+12 | 1.00E+14 | 5.00E+13 | | | 5.00E+13 |
| 7.00E+12 | | 1.00E+14 | | | |
| 8.00E+12 | | | | | |
| 1.00E+13 | | | | | |
| 2.00E+13 | | | | | |
| 5.00E+13 | | | | | |

TABLE 2
ACTUAL MEASUREMENT CONDITION

| | |
|---|---|
| w/oESD-P+ | STRUCTURE OF POWER SUPPLY CLAMP |
| | FORMED BY OPENING POWER SUPPLY |
| | CLAMP PORTION IN STEP IN FIG. 47 |
| | OF FIFTH EMBODIMENT AND |
| | IMPLANTING PHOSPHORUS THEREIN, |
| | AND OMITTING STEP IN FIG. 48 |
| ReF | I/O Tr STRUCTURE IN FIFTH |
| | EMBODIMENT (PRIOR ART EXAMPLE) |
| ESD-P + 15K | STRUCTURE OF POWER SUPPLY CLAMP |
| | FORMED BY OPENING POWER SUPPLY |
| | CLAMP PORTION IN STEP IN FIG. 47 |
| | OF FIFTH EMBODIMENT AND |
| | IMPLANTING PHOSPHORUS THEREIN, |
| | AND CHANGING ACCELERATION VOLTAGE |
| | IN STEP IN FIG. 48 TO 15 keV |
| ESD-P + 10K | STRUCTURE OF POWER SUPPLY CLAMP |
| | FORMED BY OPENING POWER SUPPLY |
| | CLAMP PORTION IN STEP IN FIG. 47 |
| | OF FIFTH EMBODIMENT AND |
| | IMPLANTING PHOSPHORUS THEREIN, |
| | AND CHANGING ACCELERATION VOLTAGE |
| | IN STEP IN FIG. 48 TO 10 keV |
| LDD + SDE/ | STRUCTURE OF I/O Tr FORMED BY |
| PKTonly | OPENING I/O Tr PORTION ENTIRE |
| | SURFACE AND IMPLANTING ARSENIDE |
| | AND BF₂ IN STEP IN FIG. 49 OF |
| | FIFTH EMBODIMENT |

According to the present invention, drain junction of the protection transistor is sharper than that in the internal region, and therefore the frequency of occurrence of the avalanche multiplication phenomenon becomes high in the protection transistor. As a result, the substrate potential of the protection transistor easily rises, and the voltage which starts the parasitic bipolar operation, namely, the voltage which causes snap-back becomes lower than that of the internal transistor. Accordingly, even if the ESD surge occurs to the power supply pad, the protection transistor is brought into the ON state prior to the internal transistor. Therefore, over current does not flow into the internal circuit, and thus the internal circuit can be properly protected.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A semiconductor device, comprising:
an internal transistor constructing an internal circuit; and
a protection transistor which protects said internal transistor from breakage due to static electricity occurring between power supply pads, a conductivity type of a channel of said protection transistor corresponding to a conductivity type of said internal transistor, and drain junction of said protection transistor being sharper than drain junction of said internal transistor.

2. The semiconductor device according to claim 1, wherein an impurity concentration of the channel of said protection transistor is higher than that of a channel of said internal transistor.

3. The semiconductor device according to claim 1, wherein said protection transistor has an impurity diffusion layer formed between the channel and a drain, having a higher impurity concentration than the channel, and having the same conductivity type as the channel.

4. The semiconductor device according to claim 1, wherein an impurity concentration of a drain of said protection transistor is higher than that of a drain of said internal transistor.

5. The semiconductor device according to claim 1, wherein said internal transistor and protection transistor are n-channel MOS transistors.

6. The semiconductor device according to claim 1, further comprising a second protection transistor which protects said internal transistor from breakage due to static electricity occurring to an input and output pad.

7. The semiconductor device according to claim 6, further comprising a resistance element connected between said second protection transistor and said internal circuit.

8. The semiconductor device according to claim 6, wherein said second protection transistor is an n-channel MOS transistor.

9. A manufacturing method of a semiconductor device, comprising the step of:
forming an internal transistor constructing an internal circuit, and a protection transistor which protects the internal transistor from breakage due to static electricity occurring between electric power pads, a conductivity type of a channel of the protection transistor being made to correspond to a conductivity type of the internal transistor, and drain junction of the protection transistor being made sharper than drain junction of the internal transistor.

10. The manufacturing method according to claim 9, wherein said step of forming the protection transistor comprises the step of forming a channel having a higher impurity concentration than that of a channel of the internal transistor.

11. The manufacturing method according to claim 9, wherein said step of forming the protection transistor comprises the steps of:
forming a channel;
forming a drain; and
forming an impurity diffusion layer, between the channel and the drain, having a higher impurity concentration than the channel and having the same conductivity type as the channel.

12. The manufacturing method according to claim 9, wherein said step of forming the protection transistor comprises the step of forming a drain having a higher impurity concentration than that of a drain of the internal transistor.

13. The manufacturing method according to claim 9, wherein n-channel MOS transistors are formed as the internal transistor and the protection transistor.

14. The manufacturing method according to claim 9, a second protection transistor which protects the internal transistor from breakage due to static electricity occurring to an input and output pad is formed in parallel with the internal transistor and the protection transistor.

15. The manufacturing method according to claim 14, wherein an n-channel MOS transistor is formed as the second protection transistor.

16. The manufacturing method according to claim 14, wherein said step of forming the second protection transistor comprises the steps of:
forming a channel having a lower impurity concentration than the channel of the protection transistor; and
forming a part of a drain in parallel with the drain of the protection transistor.

17. The manufacturing method according to claim 9, further comprising the step of forming a second internal transistor constructing the internal circuit and operating at a lower voltage than the internal transistor, in parallel with the internal transistor and the protection transistor.

18. The manufacturing method according to claim 17, wherein an impurity concentration of a channel of the second internal transistor is made equal to that of the channel of the protection transistor.

19. The manufacturing method according to claim 9, wherein said step of forming the protection transistor comprises the steps of:
forming a drain of an LDD structure;
forming a silicide block on the drain; and
forming a silicide layer on a surface of the drain.

20. The manufacturing method according to claim 9, wherein said step of forming the protection transistor comprises the steps of:
forming a low concentration diffusion layer;
forming a silicide block on the low concentration diffusion layer;
forming a high concentration diffusion layer superposed on part of the low concentration diffusion layer with the silicide block as a mask; and
forming a silicide layer on a surface of the high concentration diffusion layer.
